(19) United States
(12) Patent Application Publication
(10) Pub. No.: US 2006/0273855 A1
(43) Pub. Date: Dec. 7, 2006

(54) Noise sensitive volume control device, audio device and noise sensitive volume control method

(75) Inventors: Hideki Matsui, Kobe-shi (JP); Shinichi Nakaishi, Kobe-shi (JP); Yuji Tomita, Kobe-shi (JP)

Correspondence Address: OLIFF & BERRIDGE, PLC, P.O. BOX 19928, ALEXANDRIA, VA, 22320, US

(73) Assignee: FUJITSU TEN LIMITED, KOBE-SHI (JP)

(21) Appl. No.: 11/447,097

(22) Filed: Jun. 6, 2006

(30) Foreign Application Priority Data
Jun. 6, 2005 (JP) 2005-166090

(51) Int. Cl. H03F 1/00; H03F 3/00

(52) U.S. Cl. 330/185; 330/192

(57) ABSTRACT

Noise information is acquired by a noise detecting microphone 2, speed information is acquired by a speed sensor 1 etc, and these items of information are inputted to a microcomputer 7. The microcomputer 7 reads a program 13 stored in a memory 8, and calculates a final correction quantity according to an instruction of the program 13. The microcomputer 7 judges whether to apply a correction quantity based on the noise information or the correction quantity based on the speed information or to increment and decrement these two types of correction quantities. Accordingly, an optimal played-back volume corresponding to a traveling condition can be outputted.

### BACKGROUND OF THE INVENTION

The present invention to relates to a noise sensitive volume control device, an audio device and a noise sensitive volume control method that automatically correct a played-back volume on the basis of speed information and noise information.

While driving a vehicle, a manual operation has hitherto been conducted for gaining an easy-to-listen volume of an audio system provided in the vehicle, corresponding to a change of sound (noise) generated in a variety of scenes. It is, however, required to perform a safety drive by concentrating on the drive during traveling, and therefore the safety drive can not be ensured by manually adjusting the volume. For solving this, devices for automatically adjusting the volume of the audio system provided in the vehicle are developed from day to day, however, the noise caused when traveling always changes depending on a variety of conditions such as a car speed and a road condition. Hence, it is required for providing comfortable music in the car that the volume can be adjusted properly corresponding to various changes of the car speed, the road condition, etc.

A technology solving the problem given above is disclosed in Japanese Patent Application Laid-Open Publication No. 6-110474 (Patent document 1). The technology disclosed in Patent document 1 is that the noise is detected by an acceleration sensor and a microphone in the car and is attenuated by utilizing respective items of information. Further, Japanese Patent Application Laid-Open Publication No. 6-85581 (Patent document 2) discloses a technology by which pieces of noise information at a certain speed, which are obtained by using a car speed sensor and the microphone, are stored in the memory, and the volume is automatically corrected based on the noise information corresponding to the speed.

### SUMMARY OF THE INVENTION

It is required for providing the comfortable music in the car by reducing the manual operation of adjusting the volume during traveling and automatically adjusting the volume of the audio system provided in the vehicle that the volume can be adjusted properly corresponding to the various changes of the car speed, the road condition, etc.

Known as technologies solving this problem are a technology of detecting the noise by the acceleration sensor and the microphone in the car and attenuating the noise by utilizing the respective items of information and a technology of storing the memory with noise information at a certain speed that are obtained by the car speed sensor and the microphone and automatically correcting the volume on the basis of the noise information corresponding to the speed. In the technology of attenuating the noise (noisy sound), however, at a deceleration time such as when approaching a toll gate during traveling on a highway, there is no alternative but to manually decrease the volume in a case where there arises a necessity of decreasing the volume. Accordingly, it is demanded to develop a technology of further reducing the manual operation of adjusting the volume during traveling.

Moreover, the technology of storing the memory with the noise information at a certain speed that are obtained by the car speed sensor and the microphone and automatically correcting the volume on the basis of the noise information corresponding to the speed, is the technology disclosed in precedence by the applicant of the present invention. This technology is that the user himself or herself manipulates a button and thus stores a traveling state in the memory, and a volume adjustment from next time is conducted in a way that depends on the past traveling state stored in the memory. A technology capable of sufficiently coping with a change of sound (noise) generated in a variety of scenes is, however, desired.

Further, in the technology of correcting the volume on the basis of the present car speed information and the present noise information, a deflection occurs in the correction quantity due to minute fluctuations in speed etc, and there also occurs a time difference from the actual deceleration till the volume decreases at the deceleration time. Hence, a volume control (technology) capable of providing more comfortable music by obviating these inconveniences is desired.

Moreover, user's needs for enjoying the music in the car keep rising year by year, and there is a demand for the volume control (technology) enabling more comfortable and safer traveling by reproducing the sound with a higher sound quality and less deterioration in sound quality, coping with a bias in volume of the sound and with the noise, and so on.

It should be noted that the technology disclosed in precedence by the applicant of the present invention includes a description with a purport of employing a car speed meter (speed information) and a microphone (noise information) as traveling state detection unit, however, there is made no specific proposal of providing the music at an optimal level corresponding to a variety of traveling states by employing these items of information in combination.

Accordingly, it is an object of the present invention to provide a noise sensitive volume control device and a control method that are capable of providing the music at a more optimal level against the noise by obviating a destabilized state of the sound due to the minute fluctuations of the speed and obviating the time difference till the volume decreases at the deceleration time owing to a combination of the speed information, the noise information, etc, and capable of ensuring the safety during traveling by reducing the manual operation for volume during traveling.

The present invention adopts the following means in order to solve the problems. Namely, a noise sensitive volume control device comprises a played-back sound adjusting unit that adjusts a played-back sound outputted from an audio source provided in a vehicle, a speed information input unit that receives an input of speed information of the vehicle, a noise information input unit that receives an input of noise information, a first correction quantity determining unit that determines a first correction quantity on the basis of the speed information, a second correction quantity determining unit that determines a second correction quantity on the basis of the noise information, a final correction quantity determining unit that determines a final correction quantity by computing the first correction quantity and the second correction quantity, and a control unit that controls the played-back sound adjusting unit on the basis of the final correction quantity determined by the final correction quantity determining unit.

According to the present invention, it is feasible to obviate the destabilized state of the sound due to the minute fluctuations of the speed and to obviate the time difference till the volume decreases at the deceleration time. As a result, the music at the optimal level can be provided.

The audio source is exemplified such as a car navigation system and a head unit that output the played-back sound. The played-back sound adjusting unit adjusts the played-back sound. The played-back sound adjusting unit can be exemplified by a DSP (Digital Signal Processor). The speed information connotes a speed of the vehicle when detected by a speed information detecting unit. The speed information can be detected by the speed information detecting unit such as a car speed sensor. The speed information is inputted to the speed information input unit. The noise information connotes a noise quantity detected by a noise information detecting unit. The noise information can be detected by the noise information detecting unit such as a noise detecting microphone. For example, the noise information detecting unit is installed in the vehicle provided with the noise sensitive volume control device, whereby the noise quantity in the vehicle can be detected.

The first correction quantity determining unit determines the played-back volume on the basis of the speed information. The first correction quantity determining unit can determine the played-back volume by using, e.g., a parameter table and reading a correction quantity corresponding the speed information therefrom. Further, the first correction quantity determining unit can determine the played-back volume according to an algorithm. It should be noted that the first correction quantity is a correction quantity acquired by the first correction quantity determining unit.

The second correction quantity determining unit determines the played-back volume on the basis of the noise information. The second correction quantity determining unit can determine the played-back volume by using, e.g., a parameter table and reading a correction quantity corresponding the noise information therefrom. Further, the second correction quantity determining unit can determine the played-back volume according to an algorithm. It should be noted that the second correction quantity is a correction quantity acquired by the second correction quantity determining unit.

The final correction quantity determining unit determines the final correction quantity by computing the first correction quantity and the second correction quantity. The computation includes a comparison between the first correction quantity and the second correction quantity. Accordingly, the computation involves, for instance, comparing the first correction quantity with the second correction quantity and determining the final correction quantity on the basis of a result of the comparison.

The control unit controls the played-back sound adjusting unit on the basis of the final correction quantity. In other words, the played-back sound adjusting unit adjusting the played-back sound outputted from the audio source is controlled by the control unit on the basis of the final correction quantity. As a result, the played-back sound becomes a sound in which the final correction quantity is reflected, i.e., the sound coping with the noise and so on.

Further, according to the present invention, the final correction quantity determining unit can include a first comparing unit that compares the first correction quantity with the second correction quantity, and a third correction quantity determining unit that sets any one of the first correction quantity and the second correction quantity as the final correction quantity on the basis of a comparison result obtained by the first comparing unit.

The correction quantity based on the speed information is compared with the correction quantity based on the noise information, and the correction quantity corresponding to a traveling condition is applied, thereby making it possible to cope with an instantaneous fluctuation in noise quantity, to cope with the noise caused by a change in condition of a road surface and by opening a window and to provide the music at an optimal level.

The first comparing unit compares the first correction quantity with the second correction quantity. The comparison between the correction quantities is a comparison about which value is larger, the first correction quantity or the second correction quantity that are read from the parameter tables by, e.g., a microcomputer. The third correction quantity determining unit determines the correction quantity on the basis of the result acquired by the first comparing unit. Specifically, the determination of the third correction quantity is, for instance, that the microcomputer determines which correction quantity, the first correction quantity or the second correction quantity, is applied according to an instruction of a program.

Still further, according to the present invention, the final correction quantity determining unit, when the second correction quantity comes to have a value larger than the first correction quantity, can set the second correction quantity as the final correction quantity.

The case in which the second correction quantity has a value larger than the first correction quantity has, is exemplified such as traveling on a bad road and traveling while opening the window. In such a case, according to the present invention, it is possible to apply the correction quantity depending on the present noise information without depending on the present car speed information. As a result, according to the present invention, the music at the optimal level can be provided.

Yet further, according to the present invention, said final correction quantity determining unit, when the second correction quantity is within the range of the correction upper limit value through the correction lower limit value which are previously set, can set the second correction quantity as the final correction quantity.

The correction upper limit value connotes an upper limit value of the first correction quantity. The correction lower limit value connotes a lower limit value of the first correction quantity. When the present noise information is extremely large or small, it is feasible to prevent the volume from becoming too large or too small by applying the correction quantity based on the present car speed information. Further, for instance, in the case of performing the abrupt deceleration, a delay occurs in convergence of the noise when the volume is corrected depending on the noise information. Natural correction can be made without causing any delay in the convergence of the noise by correcting the volume in a way that depends on the upper limit of the correction quantity of the speed information, and the music at the optimal level can be thereby provided.

It should be noted that the first correction quantity determining unit previously sets a threshold value in the speed and can determine the first correction quantity by judging that the speeds falling within a range of this threshold value are the same speed. With this contrivance, the deflection in the correction quantity due to the minute fluctuations of the car speed can be restrained.

Further, the second correction quantity determining unit previously sets a threshold value in the noise quantity and can determine the second correction quantity by judging that the noise quantities falling within a range of this threshold value are the same noise quantity. With this contrivance, the deflection in the correction quantity due to the minute noise fluctuations can be restrained.

Moreover, according to the present invention, the noise sensitive volume control device may further comprise a storage unit stored with reference speed information, wherein the final correction quantity determining unit includes a first comparing unit that compares the first correction quantity with the second correction quantity and a second comparing unit that compares the reference speed information with the speed information, and the final correction quantity determining unit determines the final correction quantity by judging whether to apply any one of the first correction quantity and the second correction quantity or to apply none of the first correction quantity and the second correction quantity on the basis of a comparison result by the first comparing unit and a comparison result by the second comparing unit.

It is possible to judge that the present traveling state is, e.g., an abrupt deceleration state by providing the unit comparing the present car speed information (speed information) with the past car speed information (reference speed information). The proper correction corresponding to the traveling state can be made by providing the unit judging the traveling state.

The reference speed information connotes the speed stored in the storage unit. For instance, the reference speed information is the information detected by the speed information detecting unit detecting the speed information and stored in the storage unit. The speed information is the speed at a point of time when detected by the speed information detecting unit. When setting the speed information as the present car speed, the reference speed information is the speed stored in the storage unit and is, when compared with the speed information, relatively the past car speed. It should be noted that the storage unit is exemplified by a memory.

The second comparing unit compares the present car speed with the past car speed. This comparison can be executed in such a manner that, e.g., the microcomputer compares the speed information with the reference speed information.

Furthermore, according to the present invention, the final correction quantity determining unit, when a speed difference between the reference speed information and the speed information is larger than a predetermined value that is set beforehand, can set the first correction quantity as the final correction quantity.

The correction based on the speed information has better respondence than the correction based on the noise information has. Accordingly, when judging, for instance, that it is the abrupt deceleration state, the correction depending on only the speed information can be made without performing the correction based on the noise information, and it is possible to conduct the instantaneous correction by preventing a sound delay and to provide the music at the optimal level by restraining the destabilized state of the sound. It should be noted that the abrupt deceleration state represents, for example, that speed differences are 20 km/h and 30 km/h. Further, the term “constant” represents a preset numerical value and is exemplified by, speaking of the above, 20 km/h and 30 km/h, however, an arbitrary value can be set without being limited these values.

Further, according to the present invention, the control unit may include a time control unit that adjusts timing when the control of the played-back sound adjusting unit is executed. The time till the correction is executed can be controlled by providing the time control unit. It should be noted that the time control unit can be exemplified by a timer.

Moreover, according to the present invention, the first correction quantity determining unit can have a car speed correction table stored with the correction quantity based on the speed information, and the second correction quantity determining unit can have a noise correction table stored with the correction quantity based on the noise information.

The correction quantity corresponding to the traveling state can be applied by computing the correction quantity (the first correction quantity) based on the speed information and the correction quantity (the second correction quantity) based on the noise information by use of the parameter tables. As a result, according to the present invention, it is feasible to cope with the instantaneous fluctuation of the noise quantity, with the change in condition of a road surface and with the noise caused by opening the window, and to provide the music at the optimal level.

The car speed correction table connotes the parameter table in which the correction quantity is parameterized for every speed. The noise correction table connotes the parameter table in which the correction quantity is parameterized for every noise quantity.

Moreover, according to the present invention, the second correction quantity determining unit can have a noise reference correction table stored with the correction quantity based on the noise information in a non-playback status.

The noise reference correction table connotes the table in which the correction quantity is parameterized for every noise quantity on the basis of the noise information detected by the noise information detecting unit in the non-playback status of the music. The optimal correction corresponding to the car type of the car provided with the noise sensitive volume control device can be made by employing the noise reference correction table in which the correction quantity is parameterized for every noise quantity serving as the reference by detecting the noise quantity serving as the reference in the non-playback status of the music.

Yet further, an audio device according to the present invention comprises an audio source, a played-back sound adjusting unit that adjusts a played-back sound played back from the audio source, a speed information input unit that receives an input of speed information of a vehicle, a noise information input unit that receives an input of noise information, a first correction quantity determining unit that determines a first correction quantity on the basis of the speed information, a second correction quantity determining unit that determines a second correction quantity on the basis of the noise information, a final correction quantity determining unit that determines a final correction quantity by computing the first correction quantity and the second correction quantity, and a control unit that controls the played-back sound adjusting unit on the basis of the final correction quantity determined by the final correction quantity determining unit.

The present invention is the audio device including the noise sensitive volume control device described above and the audio source described above. According to the present invention, the correction quantity corresponding to the traveling state is applied by comparing the correction quantity based on the speed information with the correction quantity based on the noise information, whereby it is possible to cope with the instantaneous fluctuation in noise quantity, with the change in condition of the road surface and with the noise caused by opening the window, and to provide the music at the optimal level. It should be noted that a configuration of further comprising, e.g., an output unit outputting the played-back sound in addition to the components given above, may also be taken. The output unit can be exemplified by a speaker.

Still further, a noise sensitive volume control method according to the present invention comprises a step of determining a first correction quantity from vehicle speed information to be inputted, a step of determining a second correction quantity from noise information to be inputted, a step of determining a final correction quantity by computing the first correction quantity and the second correction quantity, and a step of adjusting a played-back sound played back from an audio source on the basis of the final correction quantity.

According to the present invention, it is possible to obviate the destabilized state of the sound due to the minute fluctuations of the speed and to obviate the time difference till the volume decreases at the deceleration time. As a result, the music at the optimal level can be provided.

According to the present invention, it is feasible to provide the noise sensitive volume control device and the noise sensitive volume control method that are capable of providing the music at a more optimal level against the noise by obviating a destabilized state of the sound due to the minute fluctuations of the speed and obviating the time difference till the volume decreases at the deceleration time and capable of ensuring the safety during traveling by reducing the manual operation for the volume during traveling.

### BRIEF DESCRIPTION OF THE DRAWINGS

FIG. 1 is a block diagram showing a whole configuration including a noise sensitive volume control device according to a working example of the present invention.

FIG. 2 is a flowchart of first volume control of calculating a correction quantity according to a first working example.

FIG. 3 is a noise quantity-to-speed dynamic variation graph corresponding to FIG. 2.

FIG. 4 is a flowchart of second volume control of calculating the correction quantity according to the first working example.

FIG. 5 is a noise quantity-to-speed dynamic variation graph corresponding to FIG. 4.

FIG. 6 is a flowchart of third volume control of calculating the correction quantity according to the first working example.

FIG. 7 is a noise quantity-to-speed dynamic variation graph corresponding to FIG. 6.

FIG. 8 is a flowchart of fourth volume control of calculating the correction quantity according to the first working example.

FIG. 9 is a noise quantity-to-speed dynamic variation graph corresponding to FIG. 8.

FIG. 10 is a flowchart of fifth volume control of calculating the correction quantity according to the first working example.

FIG. 11 is a flowchart of sixth volume control of calculating the correction quantity according to the first working example.

FIG. 12 is a flowchart of seventh volume control of calculating the correction quantity according to a second working example.

FIG. 13 is a time-to-speed dynamic variation graph corresponding to FIG. 12.

FIG. 14 is a flowchart of eighth volume control of calculating the correction quantity according to the second working example.

FIG. 15 is a time-to-speed dynamic variation graph corresponding to FIG. 14.

FIG. 16 is a flowchart of ninth volume control of calculating the correction quantity according to the second working example.

FIG. 17 is a flowchart of tenth volume control of calculating the correction quantity according to the second working example.

FIG. 18 is a time-to-speed dynamic variation graph corresponding to FIG. 17.

FIG. 19 is a flowchart of eleventh volume control of calculating the correction quantity according to the second working example.

FIG. 20 is a flowchart of twelfth volume control of calculating the correction quantity according to the second working example.

FIG. 21 is a flowchart of thirteenth volume control of calculating the correction quantity according to the second working example.

FIG. 22 is a flowchart of fourteenth volume control of calculating the correction quantity according to the second working example.

FIG. 23 is a flowchart of fifteenth volume control of calculating the correction quantity according to the second working example.

FIG. 24 is a flowchart of sixteenth volume control of calculating the correction quantity according to the second working example.

FIG. 25 is a flowchart of seventeenth volume control of calculating the correction quantity according to a third working example.

FIG. 26 is a flowchart of eighteenth volume control of calculating the correction quantity according to the third working example.

FIG. 27 is a flowchart of nineteenth volume control of calculating the correction quantity according to the third working example.

FIG. 28 is a flowchart of twentieth volume control of calculating the correction quantity according to the third working example.

FIG. 29 is a flowchart of twenty first control of calculating the correction quantity according to the third working example.

FIG. 30 is a diagram showing a car speed correction table, a noise reference correction table and an actual correction quantity.

FIG. 31 is a diagram showing the car speed correction table, a car model corresponding noise correction table and the actual correction quantity.

FIG. 32 is a diagram showing the car speed correction table, the car model corresponding noise correction table and the actual correction quantity.

### DETAILED DESCRIPTION OF THE INVENTION

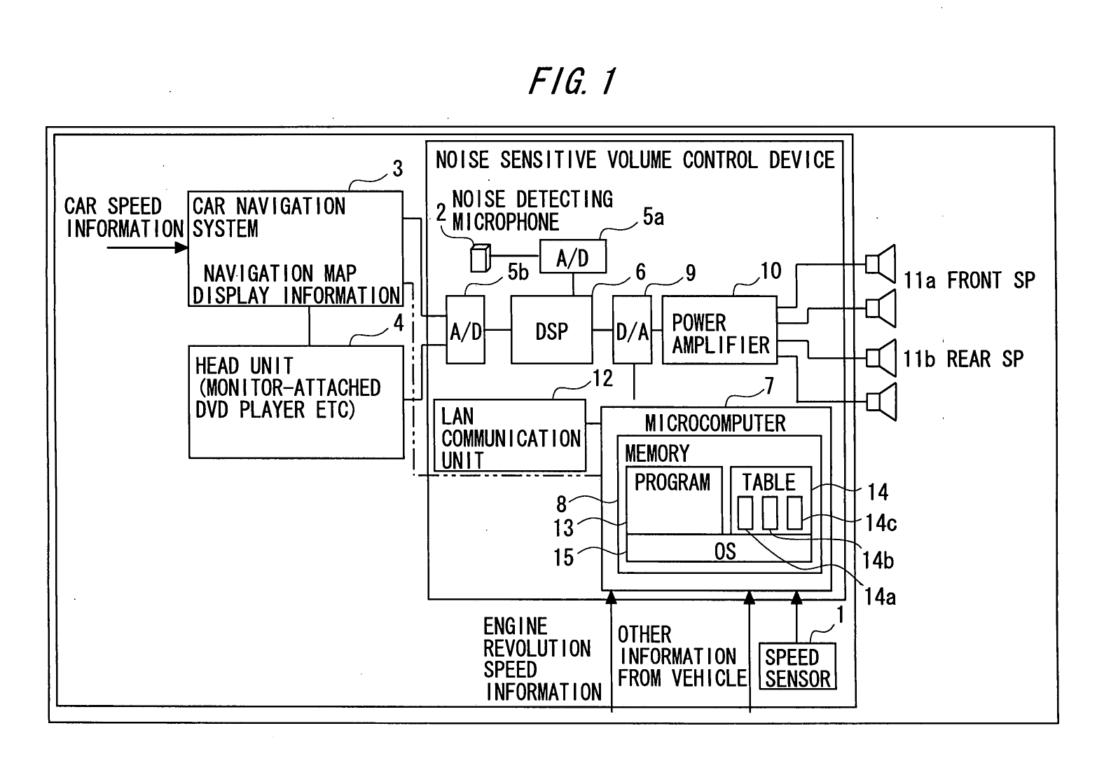

Next, an embodiment of the present invention will be explained with reference to the drawings. FIG. 1 is a block diagram showing a whole configuration of a noise sensitive volume control device according to the embodiment of the present invention.

As shown in FIG. 1, an audio device 60 is provided in a vehicle 50. The audio device 60 takes a configuration including a car navigation system 3 and a head unit 4 that configure an audio source, a noise detecting microphone 2, a speed sensor 1, A/D converters 5a, 5b, a D/A converter 9, a DSP (Digital Signal Processor) 9 corresponding to a played-back sound adjusting unit according to the present invention, a microcomputer (which will hereinafter be abbreviated to a [MC]) 7, a memory 8, a program 13, a table 14, an operating system (which will hereinafter be abbreviated to [OS]) 15, which components 8, 13, 14 and 15 are installed in the microcomputer 7, a power amplifier 10, a LAN communication unit 12 and speakers 11a, 11b, which components 2 through 12 configure the noise sensitive volume control device. It should be noted that the microcomputer 7 executes processes of a first correction quantity determining unit, a second correction quantity determining unit and a final correction quantity determining unit according to the present invention. The DSP 6 may take a configuration of its being installed in the microcomputer 7. Moreover, as shown in FIG. 1, the table 14 may include a car speed correction table 14a, a noise correction table 14b and a noise reference correction table 14c.

Further, the noise sensitive volume control device can be also configured by the microcomputer 7. In this case, the noise detecting microphone 2 is provided outside the audio device 60, wherein noise information detected by the noise detecting microphone 2 is inputted to the noise sensitive volume control device (microcomputer 7). Moreover, the speed sensor 1 is provided outside the audio device 60, wherein speed information detected by the speed sensor 1 is inputted to the noise sensitive volume control device (microcomputer 7). In the case of configuring the noise sensitive volume control device by use of the microcomputer 7, the microcomputer 7 can correspond to a speed information input unit and a noise information input unit. Note that the LAN communication unit 12 may be omitted. Moreover, the power amplifier 10 may be provided outwardly of the audio device 60.

In a case where music is played back from a CD, an MD, etc by the head unit 4 during traveling, an analog signal outputted from the head unit 4 is converted into a digital signal by the A/D converter 5b, and the digital signal is sound-adjusted by the DSP 6 and then inputted to the D/A converter 9.

On the other hand, a noise quantity (noise information) is acquired by the noise detecting microphone 2 and is converted into a digital signal by the A/D converter 5a, and this digital signal is inputted to the microcomputer 7.

Further, the speed information is acquired by the speed sensor 1 and the car navigation system 3 and is inputted to the microcomputer 7. Note that when acquiring the speed information from the car navigation system 3, for example, the speed information given from the car navigation system 3 may be transmitted to the LAN communication unit 12 and inputted to the microcomputer 7.

The microcomputer 7 determines the final correction quantity (the correction quantity to be applied) in accordance with an instruction of the program 13 on the basis of the speed information and the noise information. A music playback volume is determined based on the thus-determined final correction quantity by the microcomputer 7 and is outputted as a sound adjusting control digital signal of the DSP 6. Then, this digital signal is sound-adjusted by the DSP 6, then converted into an analog signal by the D/A converter 9, subsequently amplified by the power amplifier 10 and is outputted from the speakers 11a, 11b.

In working examples that will hereinafter be exemplified, a process till the final correction quantity is calculated according to the program 13 since the speed information and the noise information have been inputted to the microcomputer 7, will be explained with reference to flowcharts and noise quantity-to-speed dynamic variation graphs.

### Embodiment 1

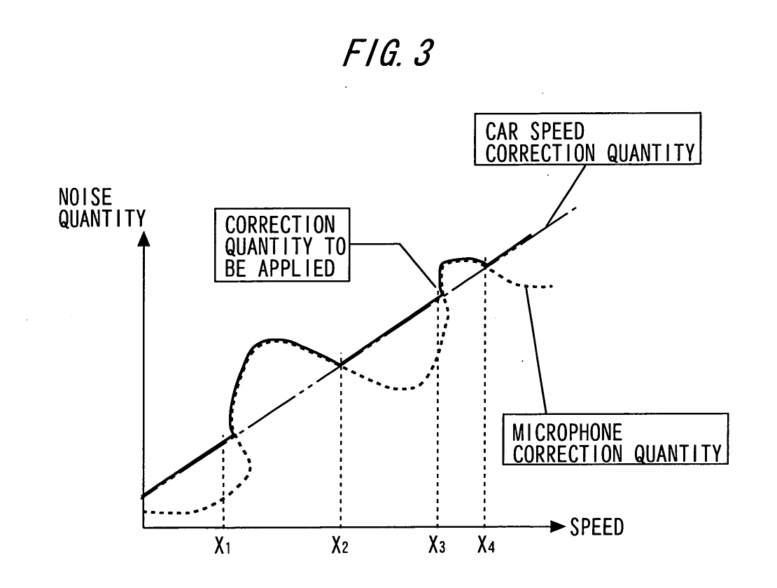

The speed information detected by the speed sensor 1 is inputted to the microcomputer 7. The microcomputer 7 determines the correction quantity (a first correction quantity) by referring to the car speed correction table 14a. This process that “the microcomputer 7 determines the correction quantity (the first correction quantity) by referring to the car speed correction table 14a”, corresponds to a process executed by a first correction quantity determining unit. Further, the noise information detected by the noise detecting microphone 2 is inputted to the microcomputer 7. The microcomputer 7 determines the correction quantity (a second correction quantity) by referring to the noise correction table 14b. This process that “the microcomputer 7 determines the correction quantity (the second correction quantity) by referring to the noise correction table 14b”, corresponds to a process executed by a second correction quantity determining unit. It is to be noted that the car speed correction table 14a and the noise correction table 14b may involve using a parameter table containing such subdivided items as to correspond to, for instance, the noise quantity-to-speed dynamic variation graph shown in FIG. 3. As a result, the program can be executed more precisely.

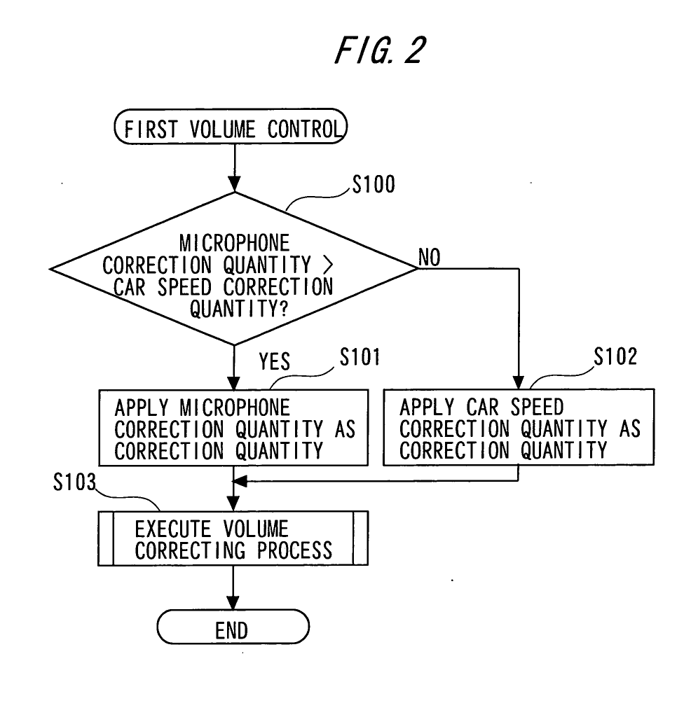

FIG. 2 shows a flowchart of first volume control of executing a volume correction process in a way that compares a car speed correction quantity with a microphone correction quantity and applies the microphone correction quantity when the microphone correction quantity exceeds the car speed correction quantity. The car speed correction quantity connotes the first correction quantity. The microphone correction quantity connotes the second correction quantity. The process of “comparing the car speed correction quantity with the microphone correction quantity” corresponds to a process executed by a first comparing unit. The process of “applying the microphone correction quantity when the microphone correction quantity exceeds the car speed correction quantity” corresponds to a process executed by a third correction quantity determining unit.

The microcomputer 7 compares the car speed correction quantity (the first correction quantity) with the microphone correction quantity (the second correction quantity) (step S100). When the microphone correction quantity exceeds the car speed correction quantity, the microphone correction quantity is applied (step S101), and the volume correcting process is executed (step S103).

Whereas when the microphone correction quantity does not exceed the car speed correction quantity in step S100, the microcomputer 7 applies the car speed correction quantity as the correction quantity (step S102) and executes the volume correcting process (step S103).

FIG. 3 is a noise quantity-to-speed dynamic variation graph corresponding to FIG. 2. A solid line represents the correction quantity (the final correction quantity) to be applied. A broken line represents the microphone correction quantity. A two-dotted chain line represents the car speed correction quantity. As shown in FIG. 3, the car speed correction quantity is depicted by a straight line extending upward and rightward. By contrast, the microphone correction quantity depicts a curved line because of being affected by a variety of conditions such as opening a window during traveling and traveling on a bad road. Speeds X1 to X2 and speeds X3 to X4 show the cases of traveling while opening the window and traveling on the bad road. As shown in FIG. 3, under the volume control in step S100 through step S103 (see FIG. 2), the microphone correction quantity is applied only at the speeds X1 to X2 and the speeds X3-X4.

The volume control described above enables the operation to get flexible to the noise in a manner that does not depend on the car speed as in the case of traveling on the bad road and traveling while opening the window.

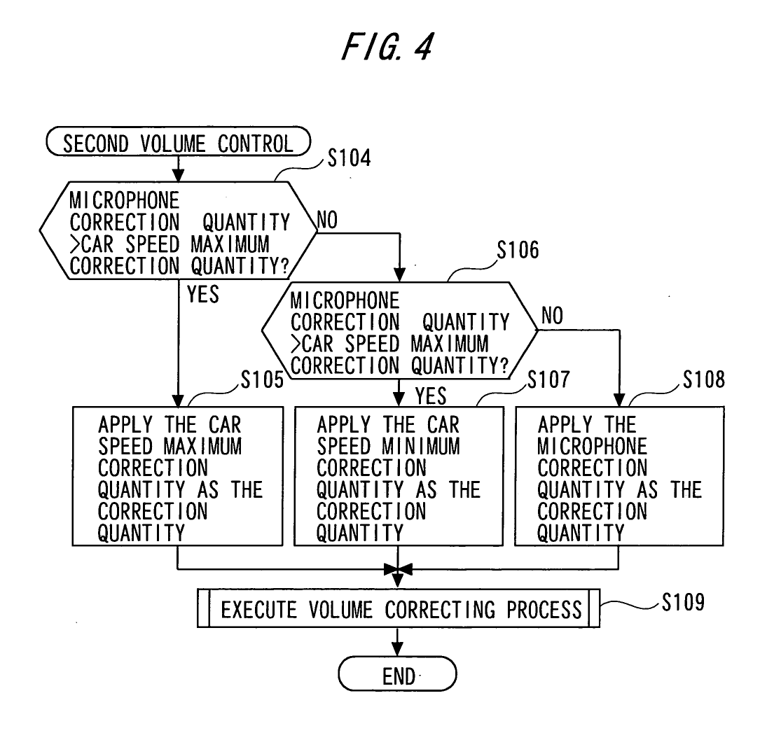

FIG. 4 shows a flowchart of second volume control of applying the microphone correction quantity only when, a width being given to the car speed correction quantity, this width includes the microphone correction quantity in the volume control. The process of “applying the microphone correction quantity only when, a width being given to the car speed correction quantity, this width includes the microphone correction quantity”, corresponds to a process executed by a third correction quantity determining unit. The width of correction quantity connotes a range of within a correction upper limit value to a correction lower limit value which are previously set.

The microcomputer 7 compares a car speed maximum correction quantity (a correction upper limit value) with the microphone correction quantity (step S104). Next, the microcomputer 7, when the microphone correction quantity exceeds the car speed maximum correction quantity, applies the car speed maximum correction quantity (step S105), and executes the volume correcting process (step S109).

Whereas when the microphone correction quantity does not exceed the car speed maximum correction quantity in step S104, the microcomputer 7 compares a car speed minimum correction quantity with the microphone correction quantity. The microcomputer 7, when the microphone correction quantity is smaller than the car speed minimum correction quantity, applies the car speed minimum correction quantity as the correction quantity (step S107), and executes the volume correcting process (step S109).

Further, where when the microphone correction quantity is not smaller than the car speed minimum correction quantity in step S106, the microcomputer 7 applies the microphone correction quantity as the correction quantity (step S108), and executes the volume correcting process (step S109).

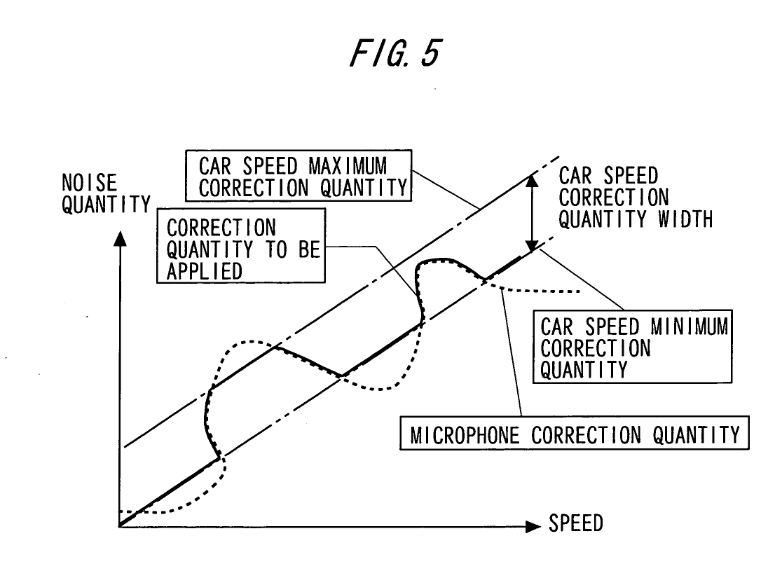

FIG. 5 is a noise quantity-to-speed dynamic variation graph corresponding to FIG. 4. A solid line represents the correction quantity to be applied. A broken line represents the microphone correction quantity. A one-dotted chain line represents the car speed maximum correction quantity. A two-dotted chain line represents the car speed minimum correction quantity. As shown in FIG. 5, the car speed correction quantity is depicted by a straight line extending upward and rightward. By contrast, the microphone correction quantity depicts a curved line because of being affected by a variety of conditions such as opening the window during traveling and traveling on the bad road. As shown in FIG. 5, a width is given to the car speed correction quantity, wherein the microphone correction quantity is applied only when included in this width.

With this contrivance, when the noise quantity (noise information) is extremely large or small, it is possible to prevent the volume from becoming too loud or too feeble by applying the correction quantity based on the speed information. Further, in case abrupt deceleration or acceleration occurs, when the volume is corrected depending on the noise information, a delay occurs in convergence of the noise, however, it is feasible to provide the music at an optimal level in a way that makes the natural correction without causing any delay in the convergence of the noise by correcting the volume depending on the upper limit of the correction quantity in the speed information.

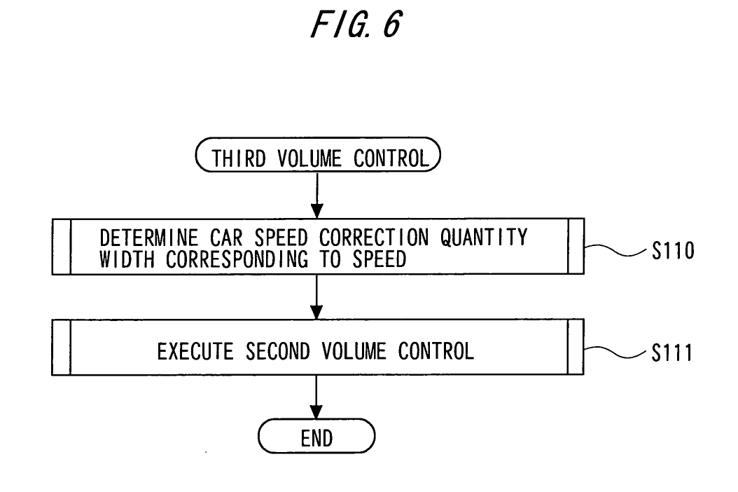

FIG. 6 shows a flowchart of third volume control of changing the width of the correction quantity based on the speed information in accordance with the speed in the volume control. The microcomputer 7 changes the width of the correction quantity based on the speed information (step S110), and thereafter executes the second volume control (step S111).

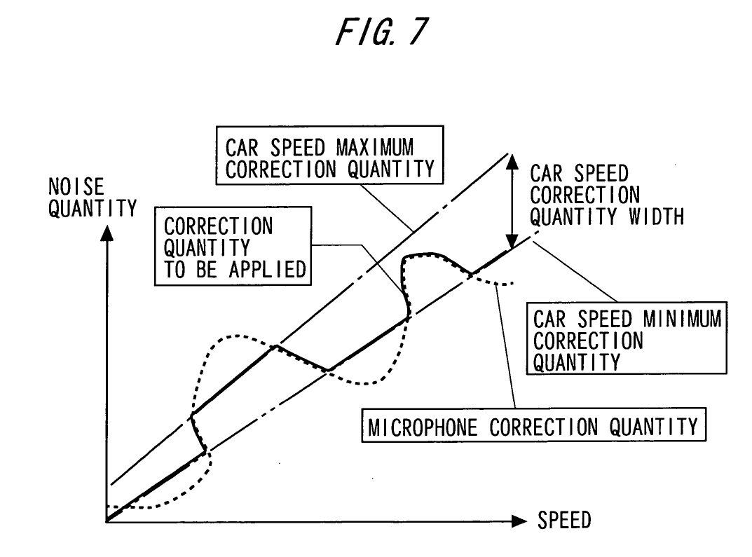

FIG. 7 is a noise quantity-to-speed dynamic variation graph corresponding to FIG. 6. A solid line represents the correction quantity (the final correction quantity) to be applied. A broken line represents the microphone correction quantity. A one-dotted chain line represents the car speed maximum correction quantity. A two-dotted chain line represents the car speed minimum correction quantity. As shown in FIG. 7, the car speed correction quantity is depicted by a straight line extending upward and rightward. By contrast, the microphone correction quantity depicts a curved line because of being affected by a variety of conditions such as opening the window during traveling and traveling on the bad road. As shown in FIG. 7, a width is given to the car speed correction quantity, and the width is set larger as the speed gets higher, wherein the microphone correction quantity is applied only when the microphone correction quantity is included in this width.

There is a difference in the noise quantity caused, it might be assumed, by opening the window and otherwise between when the car speed is high and when the car speed is low. When the speed is high, however, the optimal correction quantity can be ensured by increasing the car speed correction quantity width.

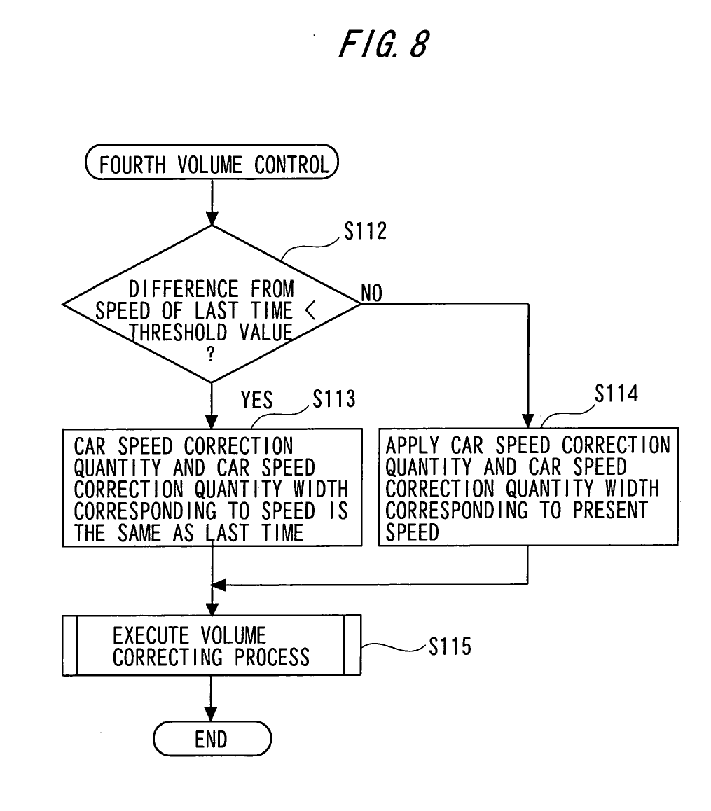

FIG. 8 is a flowchart of fourth volume control of executing the volume correcting process by providing, in the volume control., a threshold value of the speed and judging that the speeds fluctuating to such a degree as to fall within the threshold value of the speed are the same speed.

The microcomputer 7 calculates a difference in speed for the fixed period, and compares this speed difference with the threshold value of the speed (step S112). When judging that the speed difference is smaller than the threshold value of the speed, the microcomputer 7 executes the volume correcting process without changing the car speed correction quantity and the car speed correction quantity width (step S113).

While on the other hand, when judging in step S112 that the speed difference is not smaller than the threshold value of the speed, the microcomputer 7 executes the volume correcting process (step S114) by applying the car speed correction quantity corresponding to the present car speed and the car speed correction quantity width (step S114).

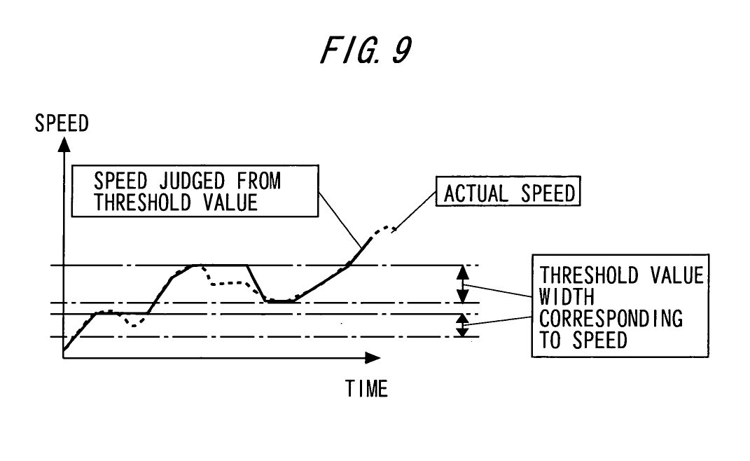

FIG. 9 is a time-to-speed dynamic variation graph corresponding to FIG. 8. A solid line represents the speed judged from the threshold value of the speed. A broken line represents the actual speed. An interval between a two-dotted chain line and a one-dotted chain line represents a width of the threshold value of the speed. As shown in FIG. 9, when the speed falls within the width of the threshold value of the speed, the microcomputer 7 executes the volume correcting process by applying the speed (solid line) judged from the threshold value of the speed.

In the speed information, if the fluctuation in car speed is corrected each time, a destabilized state appears in the sound, resulting in unnatural correction when listening. It is, however, possible to actualize the natural volume correction in a manner that restrains the destabilized state of the sound by providing the threshold value of the speed. Note that a noise threshold value corresponding to the noise can be also provided.

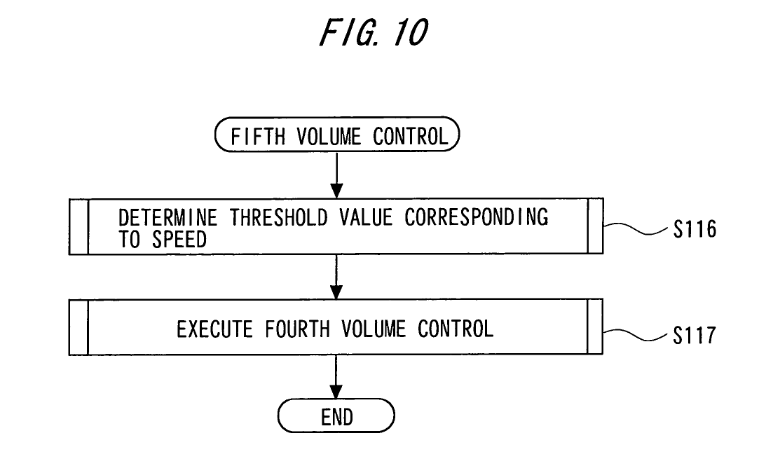

FIG. 10 is a flowchart of fifth volume control of changing the threshold value of the speed in accordance with the speed when executing the fourth volume control.

The microcomputer 7 determines the threshold value of the speed (step S116). Next, the microcomputer 7 executes the fourth volume control (step S117). For instance, as shown in FIG. 9, when the speed is low, the microcomputer 7 decreases the width of the threshold value of the speed. Further, when the speed is high, the microcomputer 7 increases the width of the threshold value of the speed. This contrivance enables actualization of the natural volume correction corresponding to the speed while restraining the destabilized state of the sound.

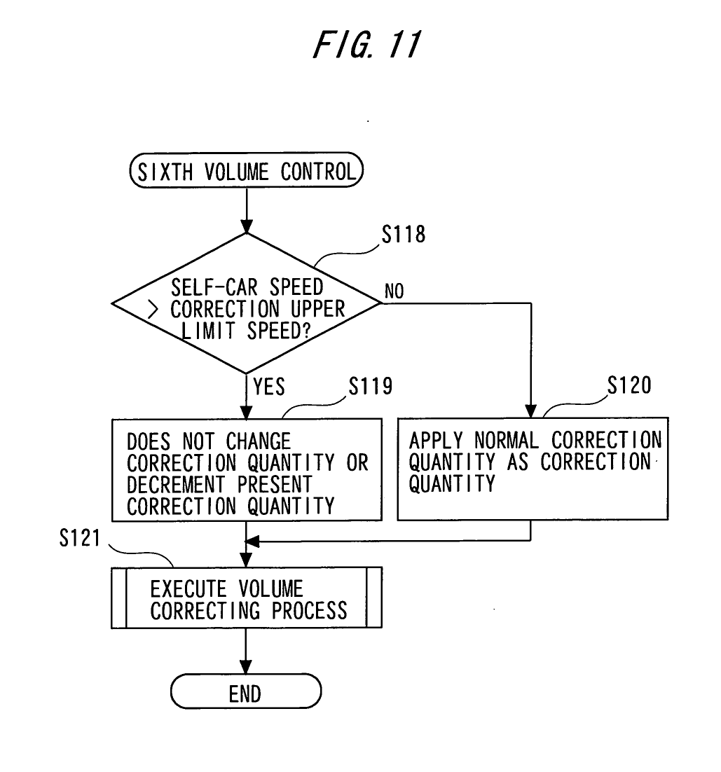

FIG. 11 shows a flowchart of sixth volume control, wherein an upper limit is set in the car speed in the speed information, when over the upper limit, the present correction quantity is not changed, or the correction is made by decrementing the present correction quantity.

The microcomputer 7 compares the upper limit speed (correction upper limit speed) set beforehand for the car speed with the present car speed (step S118). When judging that the car speed rises over the preset upper limit speed, the microcomputer 7 does not change the correction quantity or decrements the present correction quantity (step S119), and executes the volume correcting process (step S121).

While on the other hand, when judging in step S118 that the car speed is not over the preset correction upper limit speed, the microcomputer 7 uses the normal correction quantity as the correction quantity (step S120), and executes the volume correcting process (step S121). Note that the normal correction quantity connotes the correction quantity under the first volume control through the fifth volume control.

The noise gets large as the speed increases. Then, when over a certain fixed speed, it is a safety manner to have more of concentration on driving than listening to music. The safety during the driving can be improved by providing the upper limit with respect to the car speed. Further, when over the fixed speed, the driver can perceive from a change in volume when conversely decreasing the volume that the car speed exceeds the preset upper limit speed, thereby making it possible to improve the safety during the driving.

Furthermore, in the sixth volume control, in step S119, a method of subtracting from the present correction quantity without changing the present correction quantity is that the microcomputer 7, when equal to or higher than the correction upper limit speed, can decrease the volume so as to ignore both of the microphone correction quantity and the car speed correction quantity. When equal to or higher than the correction upper limit speed, the correcting process can be actualized simply by inserting a process of keeping or decrementing the correction quantity when equal to or higher than the correction upper limit speed and can be downscaled.

Moreover, in the sixth volume control, in step S119, a method of decrementing the correction quantity is that when equal to or higher than the correction upper limit speed, it is possible to follow the speed correction quantity so as to ignore the microphone correction quantity. Then, it is also feasible to set so as to reduce the correction quantities equal to or greater than the correction upper limit speed in the correction quantities in the car speed correction table. With this setting, the correcting process can be executed simply by changing the parameter in the table without changing the correcting process itself.

Further, in the sixth volume control, in step S119, a method of not changing the present correction quantity is that when equal to or higher than the correction upper limit speed, it is possible to follow the speed correction quantity so as to ignore the microphone correction quantity. Then, it is feasible to have none of the correction quantities equal to or greater than the correction upper limit speed in the correction quantities in the car speed correction table. This contrivance enables the number of the tables to be decreased and a RAM capacity to be reduced.

Moreover, the correction upper limit speed can be also determined by the user. The correction upper limit speed may be determined through an input previously given by the user and may also be determined automatically by the microcomputer 7 on the basis of road information in a way that transmits on-traveling road information (specified speed information etc) acquired by the car navigation system to the microcomputer 7.

The speed at which to desire to concentrate on driving more than listening to music might differ depending on the individual persons. A contrivance enabling the user to determine makes it possible to set the speeds corresponding to the individual persons. Further, the automatic determination based on the road information enables the user to recognize the specified speed of the traveling road from the fluctuation in volume.

### Embodiment 2

A second working example is a working example of the volume control in the case of judging that a deceleration width is large. Namely, in addition to the first working example (the first volume control through the sixth volume control) described above, the second working example is that the microcomputer 7 compares the present car speed (speed information) with a past car speed (reference speed information) stored in the memory 8, then judges that the deceleration width is large when the past car speed is higher than the present car speed and further when there is a large difference between the past car speed and the present car speed, and therefore judges that there is a large reduction quantity of the noise corresponding thereto, whereby the correction quantity follows the car speed correction quantity.

The speed information represents a speed at a point of time when a speed information detecting unit detects the speed. Supposing that the speed information is set to the present car speed, the reference speed information is the speed stored in the memory 8 and is relatively the past car speed in the case of comparing with the speed information. The process that the microcomputer 7 compares the present car speed (speed information) with the past car speed (the reference speed information) stored in the memory 8, corresponds to a process executed by a second comparing unit. It is to be noted that as a result of the comparison made by the second comparing unit, when the present car speed is lower than the past car speed and there is the large difference between the present car speed and the past car speed, the microcomputer 7 judges that the deceleration width is large. As a result, the microcomputer 7 judges that the reduction quantity of the noise is large corresponding thereto. It should be noted that the correcting process that the correction quantity follows the car speed correction quantity corresponds to a process executed by a fourth correction quantity determining unit.

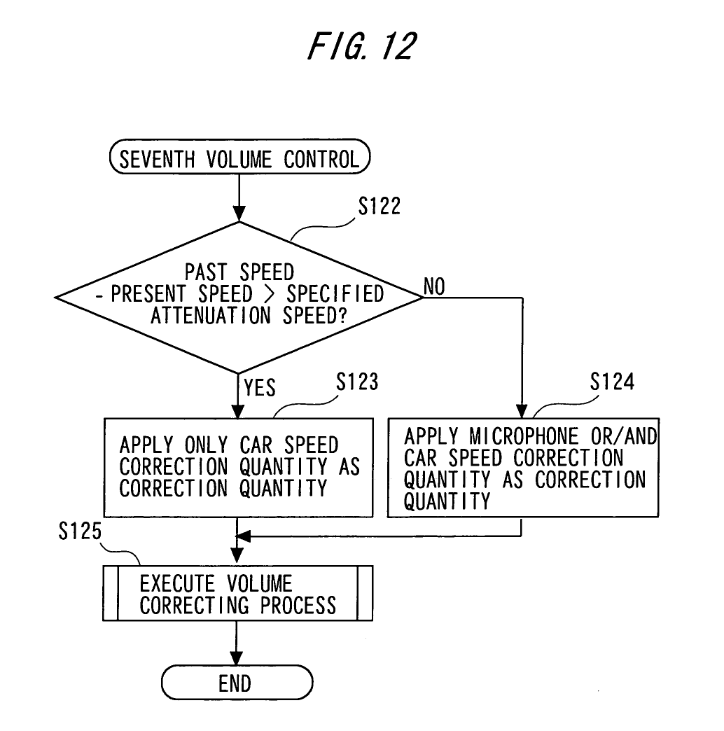

FIG. 12 shows a flowchart of seventh volume control. As shown in FIG. 12, the microcomputer 7 compares the past car speed stored in the memory 8 with the present car speed detected by the car speed sensor 1, and judges whether or not the past car speed is higher than the present car speed and whether or not a difference between the past car speed and the present car speed exceeds a specified attenuation speed (S122). When the difference between the past car speed and the present car speed is greater than the specified attenuation speed, the microcomputer 7 judges that the car is in an abrupt deceleration state, and applies only the car speed correction quantity as the correction quantity (step S123), thus executing the volume correcting process (step S125).

Whereas when it is judged in step S122 that the difference between the past car speed and the present car speed does not exceed the specified attenuation speed, the microcomputer 7 applies the correction quantity using the microphone correction quantity or the car speed correction quantity or a combination of these correction quantities as the correction quantity (step S124), and executes the volume correcting process (step S125).

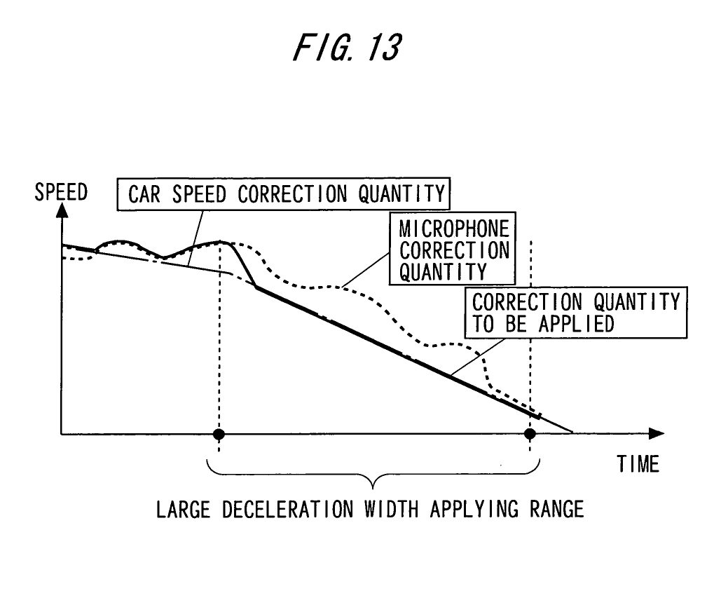

FIG. 13 is a time-to-speed dynamic variation graph corresponding to FIG. 12. A solid line represents the correction quantity to be applied. A broken line represents the microphone correction quantity. A one dotted chain line represents the car speed correction quantity. As shown in FIG. 13, when the difference between the past car speed and the present car speed exceeds the specified attenuation speed, i.e., when within a deceleration width large application range shown in FIG. 13, the car speed correction quantity is applied as the correction quantity. Note that the deceleration width connotes a difference between the past car speed and the present car speed. The deceleration width large application range connotes a range in which the deceleration width is large, and the car speed correction quantity is applied as the correction quantity.

The microcomputer 7 can judge that the present traveling state is the abrupt deceleration state by providing the means that compares the present car speed information with the past car speed information. When judging that the traveling state is the abrupt deceleration state, the microcomputer 7 does not make the correction based on the noise information and can make the correction depending on only the car speed correction quantity. The correction based on the car speed has better respondence than by correcting with the microphone. Accordingly, for example, this is preferable to a case of stopping from a high speed when paying at a highway toll gate. Namely, it is possible to avoid the excessiveness of volume and to make the natural correction without any sense of fluctuations in sound.

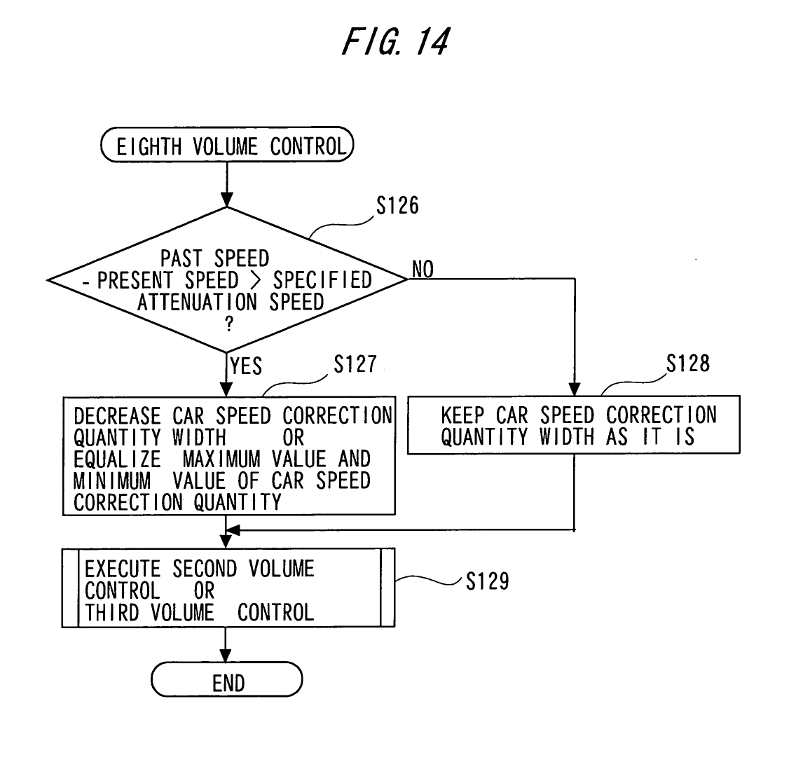

FIG. 14 shows a flowchart of eighth volume control of changing, when the deceleration width is large, a width of the car speed correction quantity in the third volume control.

The microcomputer 7 compares the past car speed with the present car speed, and judges whether or not the past car speed is higher than the present car speed and whether or not the difference between the past car speed and the present car speed exceeds the specified attenuation speed (S126). When the difference between the past car speed and the present car speed exceeds the specified attenuation speed, the microcomputer 7 judges that the car is in the abrupt deceleration state, then decreases the car speed correction quantity width or equalizes the maximum value and the minimum value of the car speed correction quantity with each other (step S127), and executes the second volume control or the third volume control (step S129).

Whereas when it is judged in step S126 that the difference between the past car speed and the present car speed does not exceed the specified attenuation speed, the microcomputer 7 does not change the car speed correction quantity width (step S128), and executes the second volume control or the third volume control (step S129).

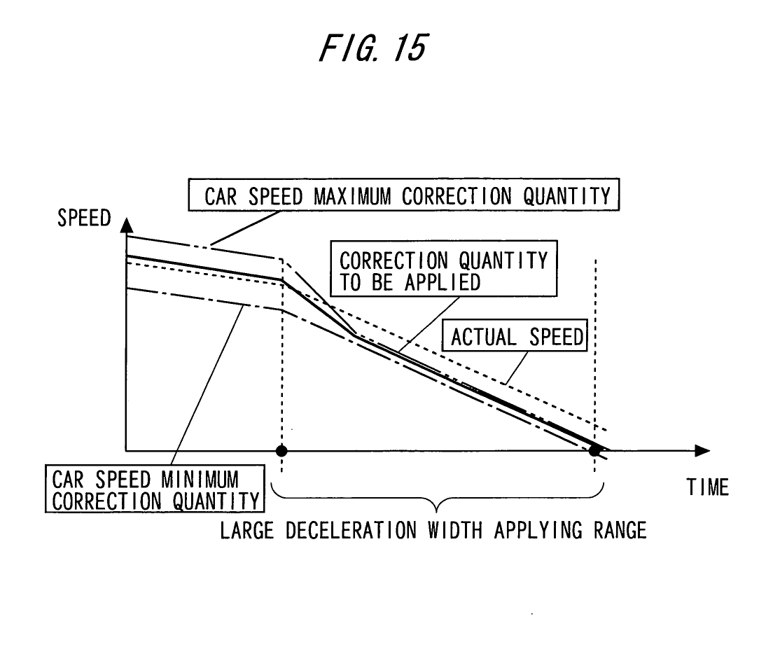

FIG. 15 is a time-to-speed dynamic variation graph corresponding to FIG. 14. A solid line represents the correction quantity to be applied. A broken line represents the actual speed. A two-dotted chain line represents the maximum car speed correction quantity. A one-dotted chain line represents the minimum car speed correction quantity. As shown in FIG. 15, when the difference between the past car speed and the present car speed exceeds the specified attenuation speed, i.e., when within a deceleration width large application range shown in FIG. 15, the car speed correction quantity width is reduced.

When abruptly decelerated, it is preferable that the volume drops down instantaneously, however, there occurs the destabilized state of the sound when the correction quantity width is large. By contract, more natural correction can be attained while restraining the destabilized state of the sound by reducing the correction quantity width.

Further, in the second working example, when judging that the deceleration width is small, the microcomputer 7 compares the speed information and the correction quantity obtained from the noise information, and can make the correction in the first working example discussed above. The natural correction can be attained by changing the way of correction based on the deceleration width.

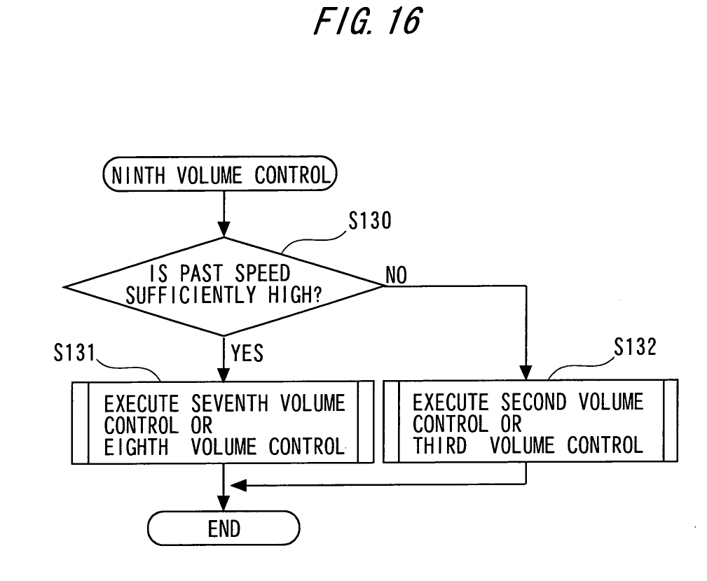

FIG. 16 shows a flowchart of ninth volume control of conducting the control based on the deceleration width described above only when judging by referring to the past car speed information that, for example, the past car speed is sufficiently high. Note that “the control based on the deceleration width” connotes the seventh or eighth volume control.

The microcomputer 7 judges by referring to the past car speed information whether or not the past car speed is sufficiently high (step S130). When judging that the past car speed is sufficiently high, the microcomputer 7 executes the seventh or eighth volume control (step S131).

While on the other hand, when judging in step S130 that the past car speed is not sufficiently high, the microcomputer 7 executes the second or third volume control (step S132).

Even if the deceleration width is constant, the noise fluctuation gets different with respect to the deceleration from an intermediate speed down the vicinity of its stop and with respect to the deceleration from the high speed down to the low speed. The present car speed is compared with the past car speed, whereby, for example, in the case of approaching the toll gate, the more natural correction can be performed by not making the correction based on the deceleration width. A speed serving as the reference speed is previously set for judging whether the past car speed is sufficiently high or not. Accordingly, for instance, when the reference speed is set to, e.g., 60 km/h, in the case of decelerating from 30 km/h down to 0 km/h in front of the toll gate on the highway, the past speed is not judged to be sufficiently high in the ninth volume control, and hence the process in step S132 is executed.

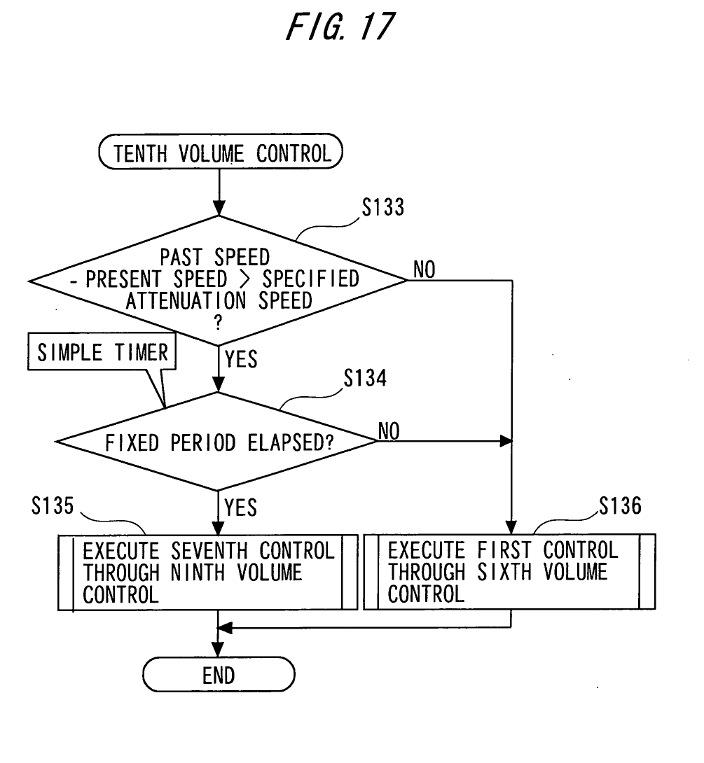

FIG. 17 shows a flowchart of tenth volume control, wherein a timer (time control unit) is provided in the noise sensitive volume control device, the time is previously inputted to the timer, and, when making the judgment that it is the abrupt deceleration, the correction based on the deceleration width is applied after an elapse of a fixed period without applying the correction based on the deceleration width described above during the fixed period.

The microcomputer 7 compares the past car speed with the present car speed and judges whether or not the difference between the past car speed and the present car speed exceeds the specified attenuation speed (S133). When the difference between the past car speed and the present car speed exceeds the specified attenuation speed, the microcomputer 7 judges that the car is in the abrupt deceleration state. Next, the microcomputer 7 judges whether or not the fixed period inputted beforehand to the timer elapses (step S134). When judging that the fixed period elapses, the microcomputer 7 executes the seventh volume control through the ninth volume control (step S135).

While on the other hand, when judging in step S133 that the difference between the past car speed and the present car speed does not exceed the specified attenuation speed, or when judging in step S134 that the fixed period inputted beforehand to the timer does not elapse, the microcomputer 7 executes the first volume control through the sixth volume control (step S136).

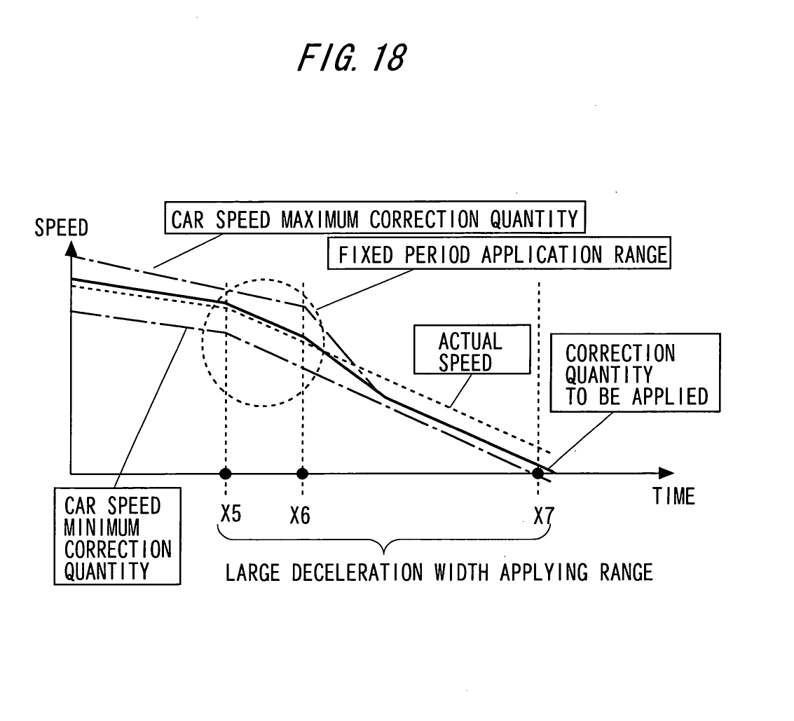

FIG. 18 is a time-to-speed dynamic variation graph corresponding to FIG. 17. A solid line represents the correction quantity to be applied. A broken line represents the actual speed. A two-dotted chain line represents the maximum car speed correction quantity. A one-dotted chain line represents the minimum car speed correction quantity. Time X5 through time X6 represent the fixed period inputted beforehand to the timer. As illustrated in FIG. 18, the seventh volume control through the ninth volume control are executed after the elapse of the fixed period.

In the case of conducting the abrupt deceleration, it is presumed that an engine brake is applied. Then, in the case of applying the engine brake, when the car speed correction quantity is instantaneously applied, it is impossible to cope with the noise of the engine brake because of the noise being loud. It is feasible to cope with the noise of the engine brake by applying the correction based on the deceleration width after the elapse of the fixed period inputted to the timer in order to correspond to this state.

Further, the judgment about whether in the deceleration state or not can be made based on, other than the information given from the car speed sensor, e.g. following items of speed information by the microcomputer 7 in a way that inputs the speed information to the microcomputer 7 from the car navigation system 3 and inputs engine revolution speed information to the microcomputer 7 from the vehicle.

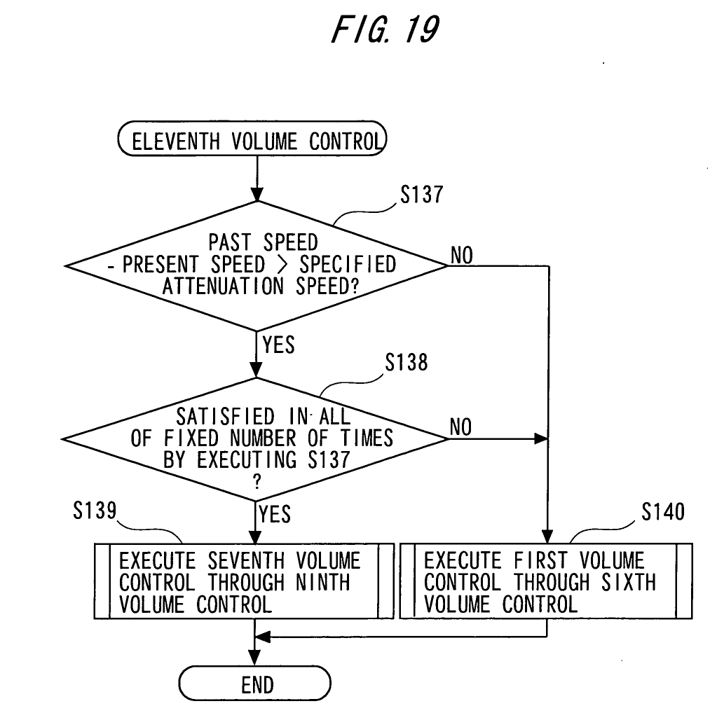

FIG. 19 shows a flowchart of eleventh volume control, wherein a counter is employed in place of the timer in the method of setting the fixed period, the step of comparing the present car speed with the past car speed is executed several times, and, after judging in all these steps that it is the abrupt deceleration state, the seventh volume control through the ninth volume control are executed.

The microcomputer 7 compares the past car speed with the present car speed and judges whether or not the difference between the past car speed and the present car speed exceeds the specified attenuation speed (step S137). When the difference between the past car speed and the present car speed exceeds the specified attenuation speed, the microcomputer 7 judges that the car is in the abrupt deceleration state. Next, the microcomputer 7 judges whether or not it is the abrupt deceleration state in all the number of times that is previously designated (step S138). When judging that it is the abrupt deceleration state in all the number of times, the microcomputer 7 executes the seventh volume control through the ninth volume control (step S138).

While on the other hand, when judging in step S137 that the difference between the past car speed and the present car speed does not exceed the specified attenuation speed, or it is not judged in step S138 that it is the abrupt deceleration state in all the pre-designated number of times, the microcomputer 7 executes the first volume control through the sixth volume control (step S140).

It is possible to reduce the RAM capacity and the unnecessary processes by using not the timer but the counter for setting the fixed period with respect to whether it is all the abrupt deceleration state or not. Further, when in the abrupt deceleration, the correction based on the deceleration width is applied, and thereafter, by use of the timer, the correction based on the speed information and the noise information can be applied after the elapse of the fixed period. With this contrivance, not at the moment when changing from the abrupt deceleration to the constant speed but after the elapse of the fixed period, the destabilized state of the sound is restrained by applying the correction based on the speed information and the noise information, whereby the natural correction can be attained.

There is provided the counter that compares the past car speed with the present car speed and counts the result of the comparison, when the present car speed is equal to the past car speed or when the difference these car speeds is equal to or smaller than the fixed value and when reaching the number of times inputted previously to the counter, the microcomputer 7 judges that it is the constant speed, and the correction based on the speed information and the noise information can be applied. A scheme of making the judgment of its' being constant speed through the counter enables the reduction of the RAM capacity and the reduction of the unnecessary processes to a greater degree than by employing the timer.

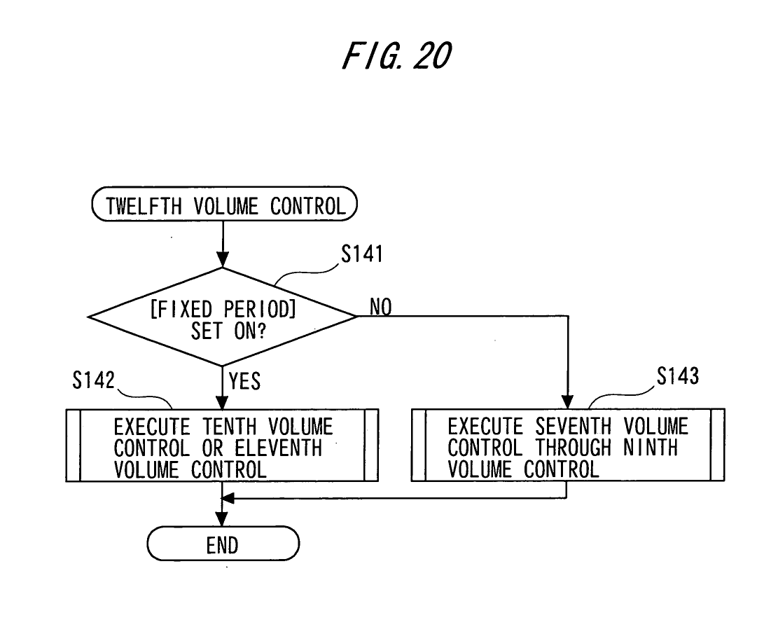

FIG. 20 shows a flowchart of twelfth volume control capable of making the correction corresponding to the driving of the user by adopting a selection button capable of setting about whether to apply the setting or non-setting of the fixed period of the volume control through the timer described above.

The noise sensitive volume control device is provided with the button that sets ON/OFF the fixed period. The microcomputer 7 judges whether the setting of the fixed period is ON or OFF (step S141). In the case of ON, the microcomputer 7 executes the tenth or eleventh volume control (step S142).

While on the other hand, in the case of setting OFF the fixed period in step S141, the microcomputer 7 executes the seventh volume control through the ninth volume control (step S143).

The selection button provided enables the user to adapt himself or herself to the user's driving. For example, in the case of a manual transmission car, the car is decelerated by the brake after using the engine brake in the majority of cases. In this case, the selection button is set ON, and the microcomputer 7 executes the tenth or eleventh volume control. In contrast, an automatic transmission car does not apply the engine brake so often. Accordingly, in this case, the selection button is set OFF, and the microcomputer 7 can execute the seventh volume control through the ninth volume control.

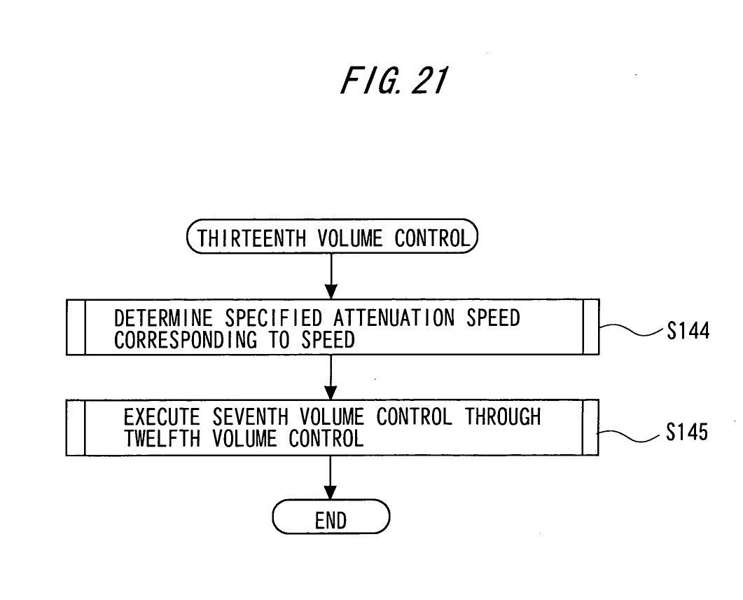

FIG. 21 shows a flowchart of thirteenth volume control in the case of determining the specified attenuation speed corresponding to the car speed in the seventh volume control through the twelfth volume control.

The microcomputer 7 determines the specified attenuation speed corresponding to the speed (step S144). Thereafter, the microcomputer 7 executes the seventh volume control through the twelfth volume control (step S145). The noise is heard differently in the abrupt deceleration from the high speed down to the intermediate speed and in the abrupt deceleration from the intermediate speed down to the low speed, and it is therefore feasible to make the correction corresponding to a situation by determining the specified attenuation speed from the present car speed. Further, when determining the specified attenuation speed from the past car speed, for instance, the speed information needs accumulating in the memory for several seconds, however, a load thereof can be reduced by setting the present car speed as the reference speed.

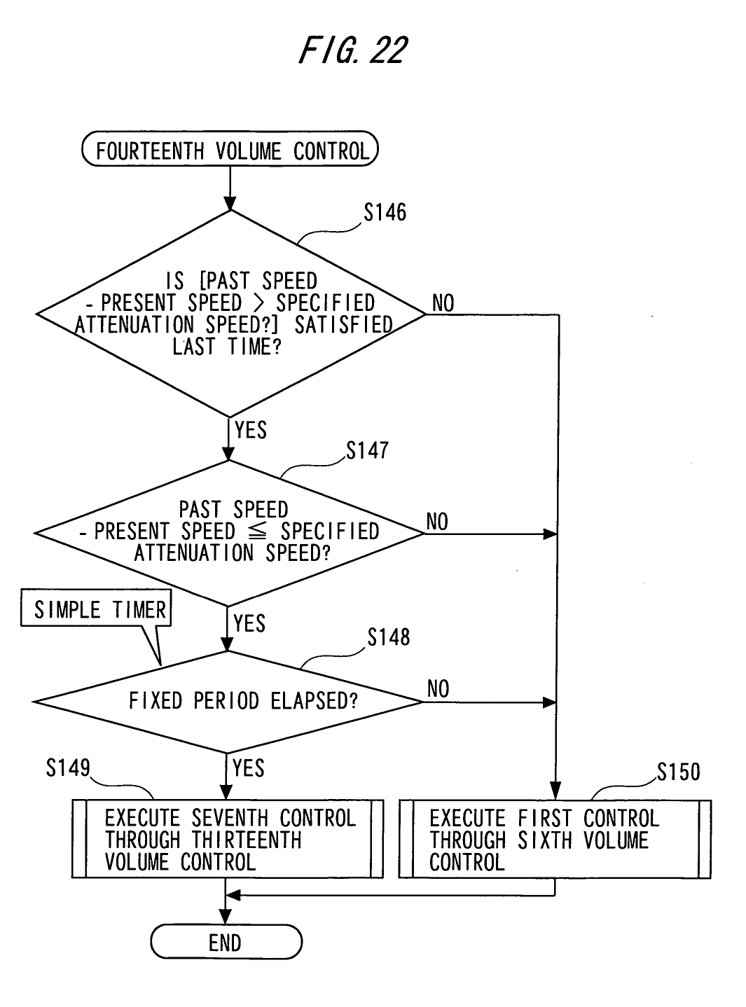

FIG. 22 shows a flowchart of fourteenth volume control of comparing the present car speed with the past car speed and, when changing from the abrupt deceleration to the constant speed, executing the seventh volume control through the thirteenth volume control after the fixed period has elapsed. Namely, the fourteenth volume control is the volume control for transition from the abrupt deceleration state to the constant speed.

As shown in FIG. 22, the microcomputer 7 judges whether or not the difference between the past car speed and the present car speed exceeds the specified attenuation speed when making the judgment of the last time (S146). When the difference between the past car speed and the present car speed exceeds the specified attenuation speed, the microcomputer 7 judges that the car is in the abrupt deceleration state. Next, the microcomputer 7 compares the past car speed with the present car speed and judges whether or not the difference between the past car speed and the present car speed is equal to or smaller than the specified attenuation speed (step S147). When judging that the difference between the past car speed and the present car speed is equal to or smaller than the specified attenuation speed, the microcomputer 7 judges whether the fixed period elapses or not (step S148). When judging that the fixed period elapses, the microcomputer 7 executes the seventh volume control through the thirteenth volume control (step S149).

While on the other hand, when judging in step S146 that the car is not in the abrupt deceleration state, when judging in step S147 that the difference between the past car speed and the present car speed is not equal to or smaller than the specified attenuation speed, and when judging in step S148 that the fixed period does not elapse, the microcomputer 7 executes the first volume control through the sixth volume control (step S150).

Through the comparison between the present car speed and the past car speed, when changing from the abrupt deceleration to the constant speed and when changed to the control in the first working example discussed above at the moment of this speed change, it becomes the correction depending on the specified car speed correction quantity width while the noise quantity detected by the noise detecting microphone 2 does not follow the actual noise quantity. As a result, the noise quantity is to be judged relatively large, and this leads to an operation of decreasing the correction quantity after increasing once the correction quantity, wherein the sound gets destabilized. The sound is, however, retrained from getting destabilized by executing the fourteenth volume control, and the more natural correction can be attained. Note that the judgment in step S148 can be made, by providing the timer, based on whether the fixed period previously inputted to this timer elapses or not.

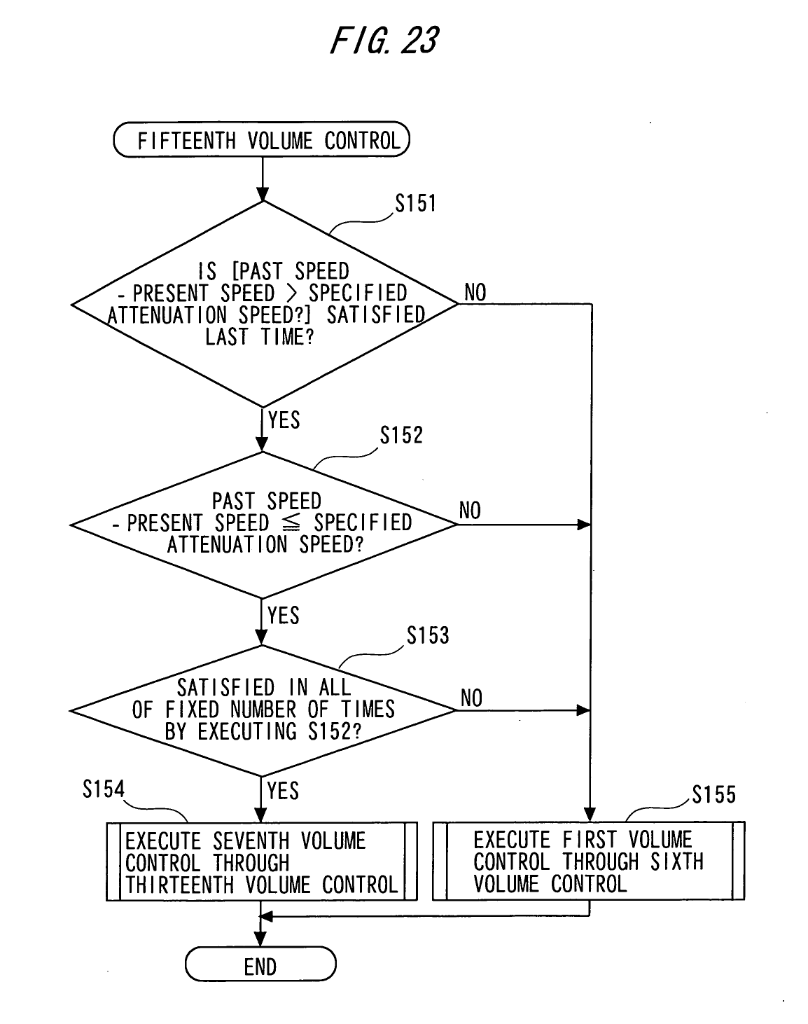

FIG. 23 shows a flowchart of fifteenth volume control, wherein the counter is employed in place of the timer in the method of setting the fixed period in the fourteenth volume control, the step of comparing the present car speed after changing to the constant speed from the abrupt deceleration with the past car speed is executed several times and, thereafter, executing the seventh volume control through the thirteenth volume control.

The microcomputer 7 judges whether or not the difference between the past car speed and the present car speed exceeds the specified attenuation speed when judging last time (S151). When the difference between-the past car speed and the present car speed exceeds the specified attenuation speed, the microcomputer 7 judges that the car is in the abrupt deceleration state. Next, the microcomputer 7 compares the past car speed with the present car speed and judges whether or not the difference between the past car speed and the present car speed is equal to or smaller than the specified attenuation speed (step S152). When judging that the difference between the past car speed and the present car speed is equal to or smaller than the specified attenuation speed, the microcomputer 7 executes step S152 a pre-designated number of times and, when judging that the difference between the past car speed and the present car speed is equal to or smaller than the specified attenuation speed in all the pre-designated number of times (step s153), executes the seventh volume control through the thirteenth volume control (step S154).

While on the other hand, when judging in step S151 that it is not the abrupt deceleration state, when judging in step S152 that the difference between the past car speed and the present car speed is not equal to or smaller than the specified attenuation speed, and when it is not judged in step S153 that the difference between the past car speed and the present car speed is equal to or smaller than the specified attenuation speed in all the pre-designated number of times, the microcomputer 7 executes the first volume control through the sixth volume control (step S155). The use of the counter makes it possible to reduce the RAM capacity and the unnecessary processes to a greater degree than by employing the timer.

### Embodiment 3

A third working example exemplifies the volume control in the case of judging that the acceleration width is large. Namely, in addition to the first working example (the first volume control through the sixth volume control) discussed above and the second working example (the seventh volume control through the fifteenth volume control) discussed above, the microcomputer 7 compares the present car speed (speed information) with the past car speed (reference speed information) stored in the memory 8, then judges that the acceleration width is large when the present car speed is higher than the past car speed and further when there is a large difference between the present car speed and the past car speed, and judges that there is also a large increase quantity of the noise corresponding thereto, whereby the correction quantity follows the car speed correction quantity.

Herein, the speed information is the speed at a point of time when detected by the speed information detecting unit. Supposing that the speed information is the present car speed, the reference speed information is the speed stored in the memory 8, and is relatively the past car speed in the case of its being compared with the speed information.

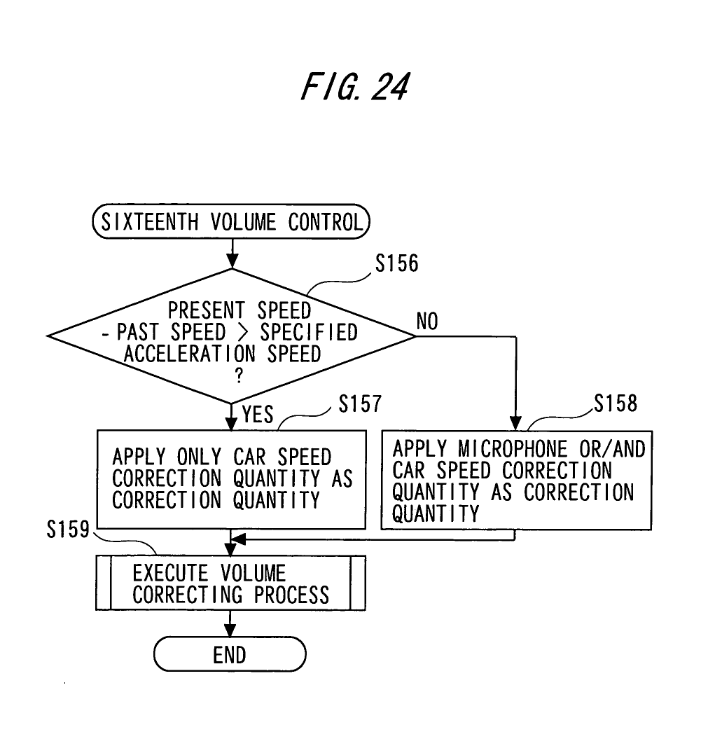

FIG. 24 shows a flowchart of sixteenth volume control. As shown in FIG. 24, the microcomputer 7 compares the past car speed stored in the memory 8 with the present car speed detected by the car speed sensor 1, and judges whether or not the present car speed is higher than the past car speed and whether or not a difference between the present car speed and the past car speed exceeds specified acceleration (S156). When the difference between the present car speed and the past car speed is greater than the specified acceleration, the microcomputer 7 judges that the car is in the abrupt deceleration state, then applies only the car speed correction quantity as the correction quantity (step S157), and executes the volume correcting process (step S159).

While on the other hand, when judging in step S156 that the difference between the present car speed and the past car speed does not exceed the specified acceleration, the microcomputer 7 applies the microphone correction quantity or the car speed correction quantity or a combination of these quantities as the correction quantity (step S158), and executes the volume correcting process (step S159).

The correction based on the car speed has the better respondence than making the correction by the microphone, and the natural correction corresponding to the abrupt acceleration such as rapid acceleration can be performed.

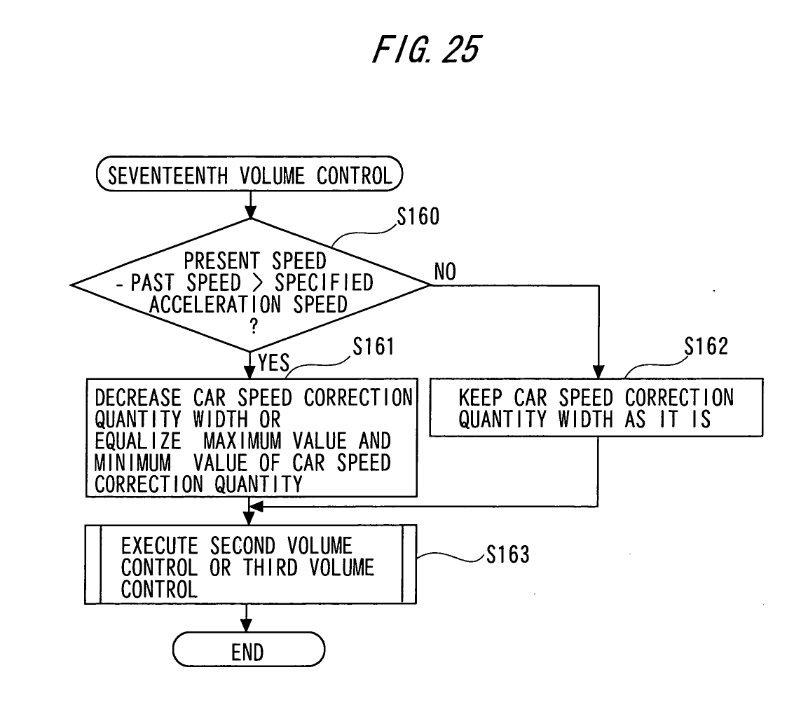

FIG. 25 shows seventeenth volume control of changing the car speed correction quantity width in the third volume control when the difference between the present car speed and the past car speed is large. Herein, the difference between the present car speed and the past car speed is referred to as an acceleration width.

The microcomputer 7 compares the past car speed with the present car speed, and judges whether or not the present car speed is higher than the past car speed and whether or not the difference between the present car speed and the past car speed exceeds the specified acceleration (S160). When the difference between the present car speed and the past car speed is greater than the specified acceleration, the microcomputer 7 judges that the car is in the abrupt deceleration state, then decreases the car speed correction quantity width or equalizes the maximum value and the minimum value of the car speed correction quantity with each other (step S161), and executes the second volume control or the third volume control (step S163).

Whereas when it is judged in step S160 that the difference between the present car speed and the past car speed does not exceed the specified acceleration, the microcomputer 7 does not change the car speed correction quantity width (step S160) and executes the second volume control or the third volume control (step S163).

When in the abrupt deceleration, it is preferable that the volume be increased instantaneously, however, when the correction quantity width is large, the destabilized state of the sound occurs, and hence the natural correction can be attained by reducing the correction quantity width.

Further, in the third working example, when judging that the acceleration width is small, the microcomputer 7 compares the speed information and the correction quantity obtained from the noise information, and can execute the correction in the first working example discussed above. The natural correction can be attained by changing the way of the correction with the acceleration width.

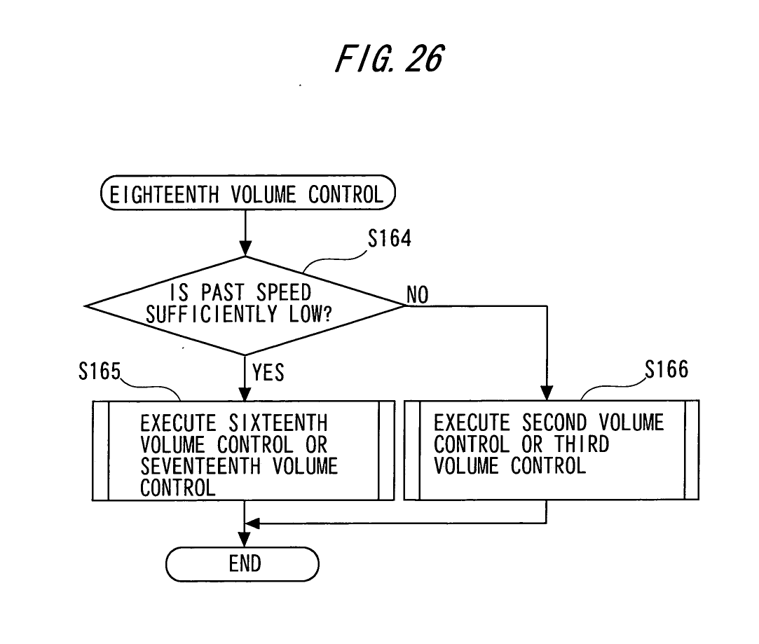

FIG. 26 shows a flowchart of eighteenth volume control of carrying out the control based on the acceleration width described above only when judging that, e.g., the past car speed is sufficiently slow by referring to not only the acceleration width but also the past car speed information. Note that “the control based on the acceleration width” connotes the sixteenth or seventeenth volume control.

The microcomputer 7 refers to the past car speed information and judges that the past car speed is sufficiently slow (step S164). When judging that the past car speed is sufficiently slow, the microcomputer 7 executes the sixteenth volume control or the seventeenth volume control (step S165).

Whereas when it is judged in step S164 that the past car speed is not sufficiently slow, the microcomputer 7 executes the second volume control or the third volume control (step S166).

Even if the acceleration width is constant, the fluctuation in noise is different in the acceleration from the stop up to the vicinity of the intermediate speed and in the acceleration from the low speed up to the high speed. In this case, the more natural correction can be attained by comparing the past car speed.

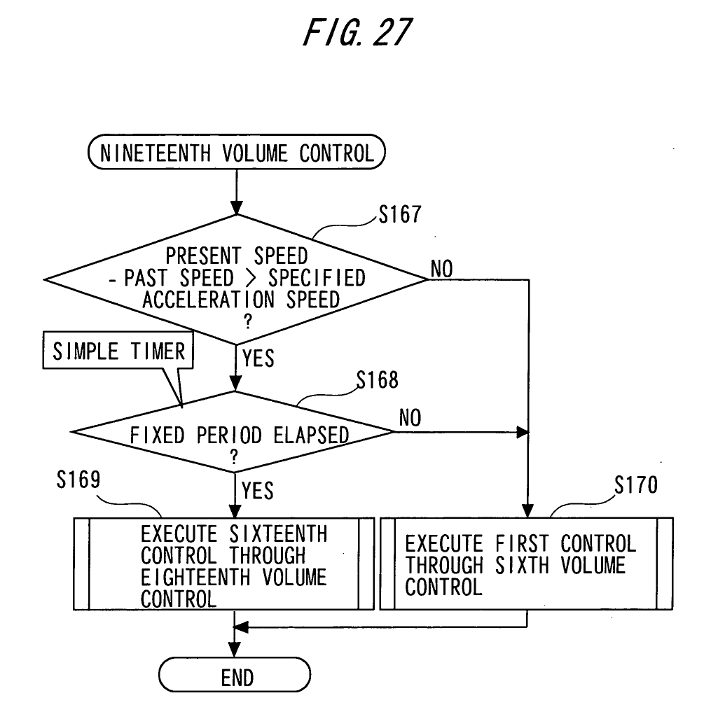

FIG. 27 shows a flowchart of nineteenth volume control, wherein the noise sensitive volume control device is provided with the timer (time control unit), the time is previously inputted to the timer, and, when judging that it is the abrupt deceleration, the correction based on the deceleration width is applied after an elapse of a fixed period without applying the correction based on the deceleration width during the fixed period.

The microcomputer 7 compares the past car speed with the present car speed and judges whether or not the difference between the present car speed and the past car speed exceeds the specified acceleration (S167). When the difference between the present car speed and the past car speed is greater than the specified acceleration, the microcomputer 7 judges that the car is in the abrupt deceleration state. Next, the microcomputer 7 judges whether the fixed period inputted beforehand to the timer elapses or not (step S168). When judging that the fixed period elapses, the microcomputer 7 executes the sixteenth volume control through the eighteenth volume control (see FIGS. 24, 25 and 26) (step S169).

While on the other hand, when judging in step S167 that the difference between the present car speed and the past car speed does not exceed the specified acceleration, or when judging in step S168 that the fixed period inputted beforehand to the timer does not elapse, the microcomputer 7 executes the first volume control through the sixth volume control (step S170).

When accelerating abruptly, it is assumed that the time is required till the gear is shifted up (to the high speed) since kickdown has been done at the initial stage of the acceleration. The timer is provided, and it is possible to cope with the noise caused by the kickdown etc by applying the correction based on the acceleration width after the elapse of the fixed period inputted to the timer.

Incidentally, for example, in the case of shifting up the gear, information that a shift change has been done is inputted to the microcomputer 7, and the process may also be executed in a way that measures the fixed period inputted beforehand to the timer since the microcomputer 7 has received the input of the information that the shift change has been done.

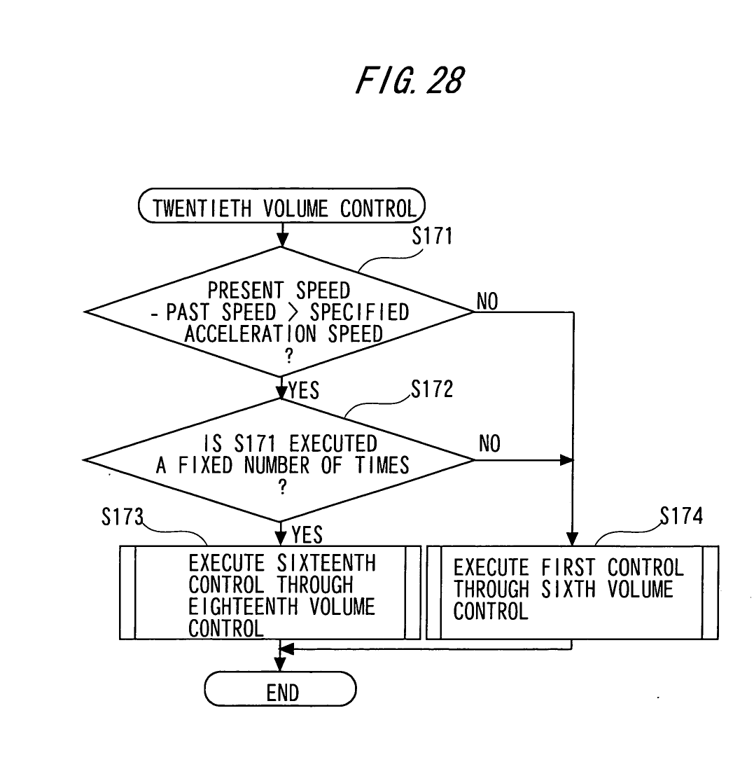

FIG. 28 shows a flowchart of twentieth volume control, wherein the counter is employed in place of the timer in the method of setting the fixed period, the step of comparing the present car speed with the past car speed is executed several times and, after judging that it is the abrupt deceleration state in all these steps, executing the sixteenth volume control through the eighteenth volume control.

The microcomputer 7 compares the past car speed with the present car speed and judges whether or not the difference between the present car speed and the past car speed exceeds the specified acceleration (S171). When the difference between the present car speed and the past car speed is greater than the specified acceleration, the microcomputer 7 judges that the car is in the abrupt deceleration state. Next, the microcomputer 7 judges whether or not it is the abrupt deceleration state in all of the pre-designated number of times (step S172). When judging that it is the abrupt deceleration state in all of the pre-designated number of times, the microcomputer 7 executes the sixteenth volume control through the eighteenth volume control (step S173).

While on the other hand when judging in step S171 that the difference between the present car speed and the past car speed does not exceed the specified acceleration, or when making none of such judgment in step S172 that it is the abrupt deceleration state in all of the pre-designated number of times, the microcomputer 7 executes the first volume control through the sixth volume control (step S174).

The setting of the fixed period is performed by not the timer but the counter concerning whether all in the abrupt deceleration state or not, thereby making it possible to reduce the RAM capacity and the unnecessary processes.

Moreover, when accelerating, the correction based on the acceleration width is applied, and, thereafter, the correction based on the speed information and the noise information can be applied after the elapse of the fixed period by use of the timer. Owing to this contrivance, the correction based on the speed information and the noise information is applied not at the moment when changing to the constant speed from the abrupt deceleration but after the elapse of the fixed period, whereby the -destabilized state of the sound is restrained and the natural correction can be attained.

Further, the noise sensitive volume control device is provided with the counter that compares the present car speed with the past car speed, and, when reaching the number of times inputted beforehand to the counter, it is judged to be the constant speed, whereby the correction based on the speed information and the noise information can be applied. The judgment of it's being the constant speed is made based on the counter, whereby the RAM capacity and the unnecessary processes can be reduced to a greater degree than by employing the timer.

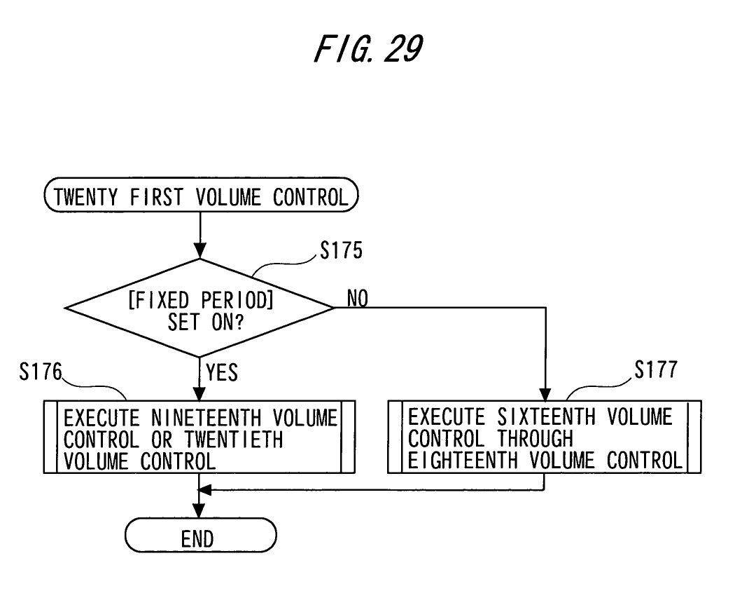

FIG. 29 shows a flowchart of twenty first volume control capable of making the correction corresponding to the driving of the user by adopting a selection button enabling the setting or non-setting of the fixed period of the volume control through the timer described above.

The button that sets ON/OFF the fixed period is provided, and the microcomputer 7 judges whether the setting of the fixed period is ON or OFF (step S175). In the case of ON, the microcomputer 7 executes the nineteenth or twentieth volume control (step S176).

While on the other hand, in the case of setting OFF the fixed period in step S175, the microcomputer 7 executes the sixteenth volume control through the eighteenth volume control (step S177).

The selection button provided enables the user to adapt himself or herself to the user's driving. For example, the selection button is set ON in the case of conducting the rapid acceleration but is set OFF in the case of not conducting the rapid acceleration so often.

ote that the deceleration width (which is the difference between the past car speed and the present car speed) in the seventh volume control and the thirteenth volume control and the acceleration width (which is the difference between present car speed and the past car speed) in the sixteenth volume control and the -nineteenth volume control may be set separately and may also be set to the same width. To be specific, the deceleration width and the acceleration width may be set to 30 km/h, and the deceleration width may be set to 30 km/h, while the acceleration width may be set to 20 km/h. With this setting, the acceleration and the deceleration can be optimally corrected. Further, it is possible to reduce the number of tables for setting, to make the comparison using an absolute value of the speed change width and to decrease the number of processes.

### Embodiment 4

The noise sensitive volume control device according to the present invention is capable of calculating the optimal correction quantity by referring to the parameters in the car speed correction tale 14a and in the noise correction table 14b that are stored in the memory 8. The parameters in the respective tables can involve using previously inputted numerical values. It is to be noted that a noise-reference correction table 14c can be provided by acquiring a reference value of the noise correction table 14b by the following method, and, as a result, an optimal correction quantity corresponding to the type of the car can be also obtained.

When traveling at the reference speed, e.g., 60 km/h without replaying the music, a noise serving as the reference (noise reference information) is detected by the noise detecting microphone 2. Next, the noise quantity generated at the reference speed is stored in the noise reference correction table 14c stored in the memory 8. Subsequently, the microcomputer 7 compares the parameter corresponding to the speed in the car speed correction table 14a and the parameter corresponding to the noise in the noise reference correction table 14c, and the car speed correction quantity can be acquired by incrementing and decrementing (addition and subtraction) the parameters in the car speed correction table 14a and in the noise reference correction table 14c.

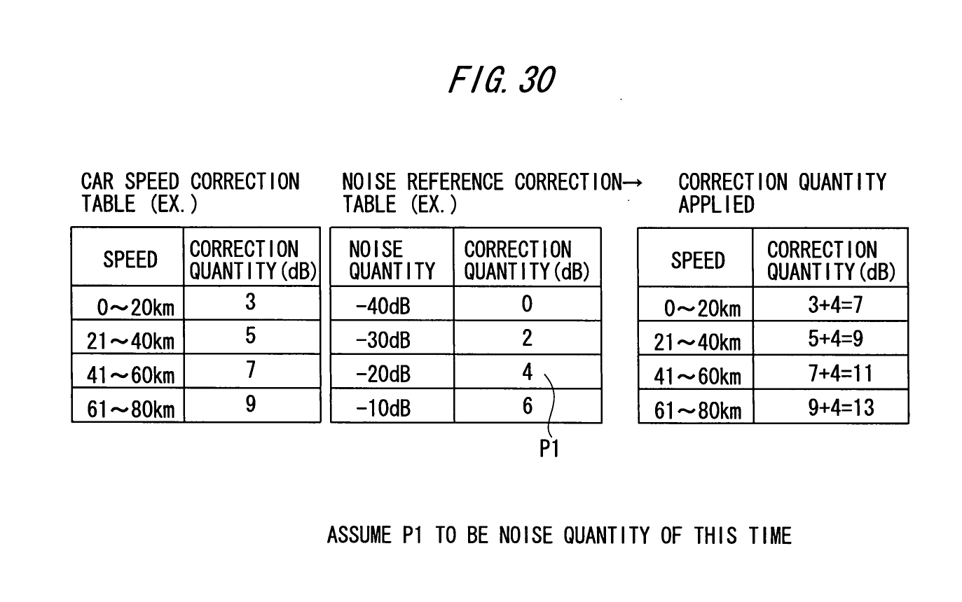

FIG. 30 shows specific examples of the car speed correction table 14a, the noise reference correction table 14c and the correction quantity to be applied.

The correction quantities are, as shown in FIG. 30, inputted to the car speed correction table 14a at, for example, a 20 km/h interval of the speed. These correction quantities may involve using the previously inputted parameters and may also be obtained by downloading etc.

Moreover, the noise reference correction table 14c is stored with the correction quantity calculated based on the noise quantity generated when traveling at the reference speed in a music non-playback state. Note that the correction quantity for the noise quantity generated when traveling at the reference speed in the music non-playback state can be calculated in such a way that the microcomputer 7 refers to a noise correction table in which the correction quantity is parameterized for every noise quantity, and reads the correction quantity corresponding to the noise quantity. The correction optimal to every type of the car can be made with the single table by correcting once on the basis of the reference speed. The type of the car is exemplified such as 1 box type, sedan and mini-van.

Considered is a case where when traveling at a speed of, e.g., 60 km/h, the noise quantity detected by the noise detecting microphone 2 is −20 dB. The microcomputer 7 reads the correction quantity corresponding to the speed of 60 km/h from the car speed correction table 14a. In this case, the car speed correction quantity is on the order of 7 dB. On the other hand, the microcomputer 7 reads, from the noise reference correction table 14c, the correction quantity corresponding to −20 dB as the noise quantity detected by the noise detecting microphone 2. In this case, the microphone correction quantity is on the order of 4 dB. Next, the microcomputer 7 increments and decrements the car speed correction quantity and the microphone correction quantity. As a result, the correction quantity to be applied is given such as 7+4=11 dB. Herein, the correction quantity read from the car speed correction table 14a is termed a first correction quantity, and the correction quantity read from the noise reference correction table 14c is termed a second correction quantity.

Moreover, the noise sensitive volume control device is provided with a car type selection button, and the noise reference correction table 14c contains the correction quantity categorized according to the car types (a car model corresponding noise correction table), wherein it is possible to select the correction quantity corresponding to the car type by use of the car type selection button.

This scheme enables the user to make the correction corresponding to the car type simply by pressing the selection button specifying the car type. Further, when the audio device has an equalizer button corresponding to the car type, the correction can be also conducted by interlocking with the equalizer button. With this contrivance, it is feasible to reduce the processes and the manual operations of the user.

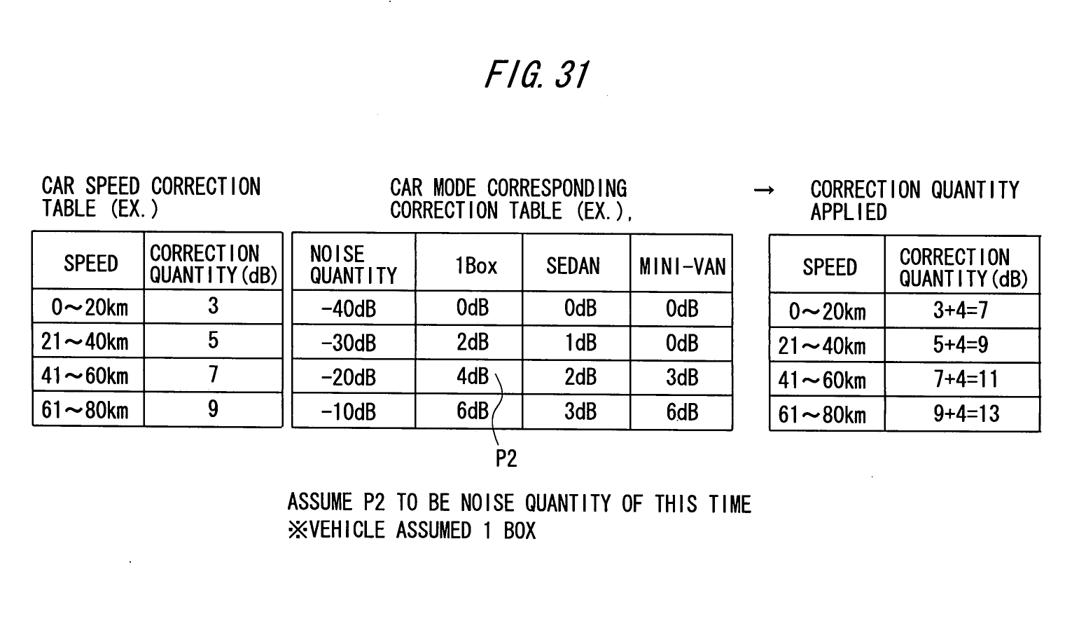

FIG. 31 shows the car speed correction table, the car model corresponding noise correction table and the correction quantity to be applied.

Considered is a case where when traveling at the speed of, e.g., 60 km/h, the noise quantity detected by the noise detecting microphone 2 is on the order of −20 dB, and a 1 box button is selected. The microcomputer 7 reads the correction quantity corresponding to the speed of 60 km/h from the car speed correction table 14a. The car speed correction quantity is on the order of 7 dB. On the other hand, the microcomputer 7 reads, from the car model corresponding noise correction table, the correction quantity corresponding to −20 dB as the noise quantity detected by the noise detecting microphone 2 in the case of selecting the 1 box button. The microphone correction quantity is on the order of 4 dB. Next, the microcomputer 7 increments and decrements the car speed correction quantity and the microphone correction quantity. As a result, the correction quantity to be applied is given by 7+4=11 dB.

Further, in the car model corresponding noise correction table, the correction quantity is previously categorized such as “High”, “Mid” and “Low” according to every correction quantity, wherein the user selects a favorite category, and the favorite correction can be thereby made.

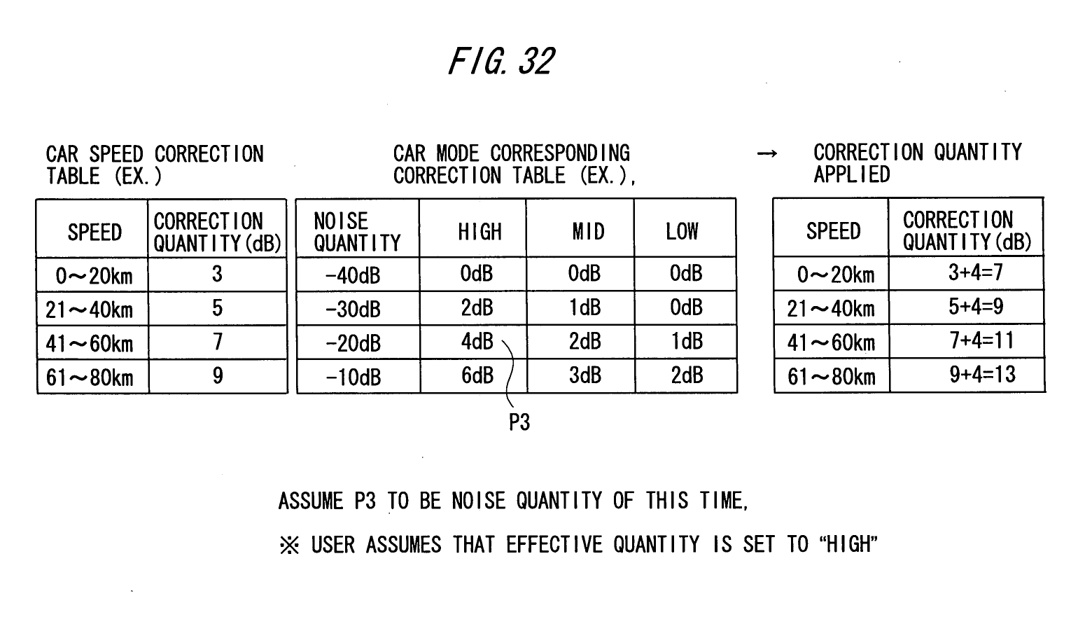

FIG. 32 shows a specific example of the car speed correction table 14a, the car model corresponding noise correction table and the correction quantity to be applied.

Considered is a case where when traveling at the speed of, e.g., 60 km/h, the noise quantity detected by the noise detecting microphone 2 is on the order of −20 dB, and a HIGH button is selected. The microcomputer 7 reads the correction quantity corresponding to the speed of 60 km/h from the car speed correction table 14a. The car speed correction quantity is on the order of 7 dB. On the other hand, the microcomputer 7 reads the correction quantity corresponding to −20 dB as the noise quantity detected by the noise detecting microphone 2 in the case of selecting the HIGH button from the car model corresponding noise correction table. The microphone correction quantity is on the order of 4 dB. Next, the microcomputer 7 increments and decrements the car speed correction quantity and the microphone correction quantity. As a result, the correction quantity to be applied is given by 7+4=11 dB.

### Other Embodiments

The volume control device according to the present invention is capable of conducting the volume control on the basis of map information acquired by the car navigation system 3 in addition to the speed information and the noise information described above. The map information is inputted to the microcomputer 7 from the car navigation system 3, and the microcomputer 7 executes the volume control by referring to the table 14 and selecting the correction quantity corresponding to a content of the map information. For instance, when a piece of toll gate anterior information showing that it is 300 m anterior to the toll gate is inputted as the map information to the microcomputer 7, the microcomputer 7 selects the correction quantity corresponding to the information that it is 300 m anterior to the toll gate by referring to the table 14, and then executes the volume control. The map information is used for the noise sensitive volume control device, whereby the music can be provided at the optimal level such as automatically decreasing the volume just anterior to the toll gate and when entering a residential street.

Further, the volume control device according to the present invention can execute the volume control on the basis of time information. The time information is inputted to the microcomputer 7 from a clock built in the car, and the microcomputer 7 conducts the volume control by referring to the table 14 and thus selecting the correction quantity corresponding to a content of the time information. When a piece of time information “22:00” is inputted as the time information to the microcomputer 7, the microcomputer 7 executes the volume control by referring to the table 14 and thus selecting the correction quantity corresponding to “22:00”. With this scheme, it is feasible to decrease the volume without depending on the speed information and the noise information when it becomes midnight and to prevent the noises from leaking from within the car in the case of traveling the residential street in midnight, and so on.

The preferred embodiments of the present invention have been discussed so far, however, the noise sensitive volume control device, the audio device and the noise sensitive volume control method according to the present invention are not limited to those embodiments, and the present invention can include combinations thereof to the greatest possible degree. Further, in the present working examples, the correction tables stored in the memory are to be employed, however, on the occasion of determining the correction quantity, the correction quantity may also be determined in the way that the microcomputer reads and sequentially executes a program based on a predetermined algorithm. Note that the predetermined algorithm connotes, e.g., a computing formula for computing the correction quantity at a certain speed.

Further, though the volume correction has been described, the present devices can be applied to such cases as to correct a frequency characteristic, a dynamic range, etc without being limited to the volume correction.

[Others]

The disclosures of Japanese patent application No.JP2005-166090 filed on Jun. 6, 2005 including the specification, drawings and abstract are incorporated herein by reference.

What is claimed is:

1. A noise sensitive volume control device comprising:
a played-back sound adjusting unit that adjusts a played-back sound outputted from an audio source provided in a vehicle;
a speed information input unit that receives an input of speed information of said vehicle;
a noise information input unit that receives an input of noise information;
a first correction quantity determining unit that determines a first correction quantity on the basis of the speed information;
a second correction quantity determining unit that determines a second correction quantity on the basis of the noise information;
a final correction quantity determining unit that determines a final correction quantity by computing the first correction quantity and the second correction quantity; and
a control unit that controls said played-back sound adjusting unit on the basis of the final correction quantity determined by said final correction quantity determining unit.

2. A noise sensitive volume control device according to claim 1, wherein said final correction quantity determining unit includes:
a first comparing unit that compares the first correction quantity with the second correction quantity; and
a third correction quantity determining unit that sets any one of the first correction quantity and the second correction quantity as the final correction quantity on the basis of a comparison result by said first comparing unit.

3. A noise sensitive volume control device according to claim 1, wherein said final correction quantity determining unit, when the second correction quantity comes to have a value larger than the first correction quantity, sets the second correction quantity as the final correction quantity.

4. A noise sensitive volume control device according to claim 1, wherein said final correction quantity determining unit, when the second correction quantity is within the range of the correction upper limit value through the correction lower limit value which are previously set, sets the second correction quantity as the final correction quantity.

5. A noise sensitive volume control device according to claim 1, further comprising a storage unit stored with reference speed information, wherein the final correction quantity determining unit includes a first comparing unit that compares the first correction quantity with the second correction quantity and a second comparing unit that compares the reference speed information with the speed information, and the final correction quantity determining unit determines the final correction quantity by judging whether to apply any one of the first correction quantity and the second correction quantity or to apply none of the first correction quantity and the second correction quantity on the basis of a comparison result by the first comparing unit and a comparison result by the second comparing unit.

6. A noise sensitive volume control device according to claim 5, wherein said final correction quantity determining unit, when a speed difference between the reference speed information and the speed information is larger than a predetermined value that is set beforehand, sets the first correction quantity as the final correction quantity.

7. A noise sensitive volume control device according to claim 1, wherein said control unit includes a time control unit that adjusts timing when the control of said played-back sound adjusting unit is executed.

8. A noise sensitive volume control device according to claim 1, wherein said first correction quantity determining unit has a car speed correction table stored with the correction quantity based on the speed information, and
said second correction quantity determining unit has a noise correction table stored with the correction quantity based on the noise information.

9. A noise sensitive volume control device according to claim 1, wherein said second correction quantity determining unit has a noise reference correction table stored with the correction quantity based on the noise information in a non-playback status.

10. An audio device comprising: an audio source;
a played-back sound adjusting unit that adjusts a played-back sound played back from said audio source;
a speed information input unit that receives an input of speed information of a vehicle;
a noise information input unit that receives an input of noise information;
a first correction quantity determining unit that determines a first correction quantity on the basis of the speed information;
a second correction quantity determining unit that determines a second correction quantity on the basis of the noise information;
a final correction quantity determining unit that determines a final correction quantity by computing the first correction quantity and the second correction quantity; and
a control unit that controls said played-back sound adjusting unit on the basis of the final correction quantity determined by said final correction quantity determining unit.

11. A noise sensitive volume control method comprising:
a step of determining a first correction quantity from vehicle speed information to be inputted;
a step of determining a second correction quantity from noise information to be inputted;
a step of determining a final correction quantity by computing the first correction quantity and the second correction quantity; and
a step of adjusting a played-back sound played back from an audio source on the basis of the final correction quantity.
